(19) United States
(12) Patent Application Publication
(10) Pub. No.: US 2022/0301810 A1
(43) Pub. Date: Sep. 22, 2022

(54) PHOTO-MICROPATTERNING FOR ELECTRON MICROSCOPY

(71) Applicants: European Molecular Biology Laboratory, Heidlberg (DE); CENTRE NATIONAL DE LA RECHERCHE SCIENTIFIQUE, Paris (FR); UNIVERSITÉ GRENOBLE ALPES, Saint-Martin-d'Hères (FR); COMMISSARIAT A L'ENERGIE ATOMIQUE ET AUX ENERGIES ALTERNATIVES, Paris (FR); INSTITUT NATIONAL DE RECHERCHE POUR L'AGRICULTURE L'ALIMENTION ET L'ENVIRONNEMENT, Paris (FR)

(72) Inventors: Julia MAHAMID, Heidelberg (DE); Mauricio TORO-NAHUELPAN, Nussloch (DE); Laurent BLANCHOIN, Grenoble (FR)

(21) Appl. No.: 17/619,822

(22) PCT Filed: Jun. 19, 2020
(86) PCT No.: PCT/EP2020/067189

§ 371 Date: Dec. 16, 2021

(30) Foreign Application Priority Data
Jun. 19, 2019 (EP) 19181388.0

(51) Int. Cl. H01J 37/20; H01J 37/28

(52) U.S. Cl. CPC H01J 37/20; H01J 37/28

(57) ABSTRACT

The invention relates to electron microscopy (EM) supports for in situ cryo-electron tomography, particularly to contactless and mask-free photo-micropatterning of EM grids for site-specific deposition of extracellular matrix-related proteins for micromachining by cryo-focused ion beam milling. The new EM supports allow for analysis of intracellular organization, permitting direct correlation of cell biology and biomechanics by 3D-structural characterization of the underlying molecular machinery in cellulo.

### FIELD OF THE INVENTION

The invention relates to the field of preparing biological specimen for microscopic analysis, particularly for the electron microscopic (EM) analysis of cells on respective EM supports. The invention particularly relates to electron microscopy (EM) supports for in situ cryo-electron tomography, particularly to contactless and mask-free photo-micropatterning of EM grids for site-specific deposition of extracellular matrix-related proteins for micromachining by cryo-focused ion beam milling. The new EM supports allow for analysis of intracellular organization, permitting direct correlation of cell biology and biomechanics by 3D-structural characterization of the underlying molecular machinery in cellulo.

### DESCRIPTION

Spatially-controlled cell adhesion on electron microscopy (EM) supports remains a bottleneck in specimen preparation for in situ cryo-electron tomography. Here, we describe a contactless and mask-free photo-micropatterning of EM grids for site-specific deposition of extracellular matrix-related proteins. We attained refined cell positioning for micromachining by cryo-focused ion beam milling. Complex patterns generate predictable intracellular organization, allowing direct correlation of cell biology and biomechanics by 3D-structural characterization of the underlying molecular machinery in cellulo.

In parallel to the ongoing resolution revolution in cryo-electron microscopy for macromolecular structure determination^{Ref.1}, cryo-electron tomography (ET) has developed further to reveal the molecular sociology in situ sensu stricto^{Ref.2-4}. Yet, cryo-ET of adherent cells, particularly mammalian cells, can only be directly performed on their thin peripheries (<300 nm). To reveal collective behaviors of macromolecules at the cell interior, thinning by advanced cryo-focused ion beam (FIB) has proved an optimal, artifact-free preparation method^{Refs.2,5,6}. Specimen preparation for cellular cryo-ET, whether performed directly on thin cellular peripheries or following FIB micromachining, routinely involves seeding of adherent cells directly on EM grids. Standard EM grids are 3 mm diameter metal meshes overlaid with a delicate perforated thin film. Cells are typically allowed to spread, subjected to genetic or molecular perturbation to represent different physiological settings to be examined in molecular detail, that are then arrested by vitrification^{Ref. 7}. For cells to be thinned by cryo-FIB, they must be positioned roughly at the center of an individual grid square (FIG. 1a)^{Ref. 6}, within a few squares away from the grid center. Whilst the first requirement is necessary to allow access to cellular material for ablation by the FIB, the latter is posed by the subsequent requirement of stage tilt in the transmission electron microscope (TEM) for collection of tomographic tilt-series. Currently, optimization of grids for cellular cryo-ET is only carried out by adjusting the concentration of the cell suspension during seeding. However, adherent cells settle and adhere randomly on grids, often in the vicinity or directly on the metal grid bars, making them inaccessible to the FIB. Furthermore, the presence of large clusters of cells increases the chance of incomplete vitrification. Such technical hurdles have made the application of state-of-the-art cellular cryo-ET cumbersome and challenging. They further limit the advance of technical developments towards automation and high-throughput sample preparation.

The present invention combines cellular cryo-ET with another technology in the fields of cell biology and biophysics, that of spatially controlled cellular environments. By adaptation of photo-micropatterning routinely applied to centimeter-scale glass slides for light microscopy-based assays^{Refs. 8,9}, functionalized EM supports were developed for directing cell positioning at high spatial accuracy, which ultimately renders molecular-resolution imaging of frozen-hydrated specimens more easily attainable.

Therefore, it was an objective of the present invention to provide means and methods that overcome the above problems associated with the analysis of biological specimen by way of electron microscopy. Other problems that have been solved and advantages associated herewith will be understood upon reading the detailed description and the experimental part of this disclosure.

### BRIEF DESCRIPTION OF THE INVENTION

Generally, and by way of brief description, the main aspects of the present invention can be described as follows:

In a first aspect, the invention pertains to a functionalized electron microscopy (EM) support comprising at least one or more area(s) functionalized with substrate allowing for the adhesion, generally speaking for the immobilization, of biological specimen, particularly live cells, wherein the area(s) is/are at least partially, preferably completely, surrounded by a passivation layer substance, wherein said substance repels cells, particularly mammalian live cells, or even does not allow for the adhesion of said live cells.

In a second aspect, the invention pertains to a method of producing the electron microscopy (EM) support referred to in the first aspect.

In a third aspect, the invention pertains to uses of the EM support forming the first aspect and that have been prepared by the methods according to the second aspect. Generally spoken, these uses relate to methods of analysing the biological specimen, e.g. adherent mammalian cells using a variety of microscopic methods, particularly EM-based methods.

In a fourth aspect, the invention pertains to a method for producing a circuit of cells.

In a fifth aspect, the invention pertains to the use of the circuit of cells in medicine.

### DETAILED DESCRIPTION OF THE INVENTION

In the following, the elements of the invention will be described. These elements are listed with specific embodiments, however, it should be understood that they may be combined in any manner and in any number to create additional embodiments. The variously described examples and preferred embodiments should not be construed to limit the present invention to only the explicitly described embodiments. This description should be understood to support and encompass embodiments which combine two or more of the explicitly described embodiments or which combine the one or more of the explicitly described embodiments with any number of the disclosed and/or preferred elements. Furthermore, any permutations and combinations of all described elements in this application should be considered disclosed by the description of the present application unless the context indicates otherwise.

In a first aspect, the invention pertains to a functionalized electron microscopy (EM) support comprising at least one or more area(s) functionalized with at least one or more substrate(s) allowing for the adhesion of biological specimen, particularly live cells, or generally for the immobilization of macromolecules, such as biological macromolecules, for example antibodies, hormones, toxins, cytokines, etc., wherein the area(s) is/are at least partially, preferably completely, surrounded by passivation layer substance, wherein said substance repels live cells and/or essentially does not allow for the adhesion of live cells. Alternatively, the passivation layer substance is a substance that prevents adhesion of live cells by at least 50% or more compared with areas that are functionalized with at least one or more substrate(s) allowing for the adhesion of biological specimen, particularly live cells.

In a second aspect, the invention pertains to a method of producing the electron microscopy (EM) support according to the first aspect.

In a third aspect, the invention pertains to uses of the EM support forming the first aspect and that have been prepared by the methods according to the second aspect.

In a fourth aspect, the invention pertains to a method for producing a circuit of cells.

In a fifth aspect, the invention pertains to the use of the circuit of cells in medicine.

The terms “of the [present] invention”, “in accordance with the invention”, “according to the invention” and the like, as used herein are intended to refer to all aspects and embodiments of the invention described and/or claimed herein.

As used herein, the term “comprising” is to be construed as encompassing both “including” and “consisting of”, both meanings being specifically intended, and hence individually disclosed embodiments in accordance with the present invention. Where used herein, “and/or” is to be taken as specific disclosure of each of the two specified features or components with or without the other. For example, “A and/or B” is to be taken as specific disclosure of each of (i) A, (ii) B and (iii) A and B, just as if each is set out individually herein. In the context of the present invention, the terms “about” and “approximately” denote an interval of accuracy that the person skilled in the art will understand to still ensure the technical effect of the feature in question. The term typically indicates deviation from the indicated numerical value by ±20%, ±15%, ±10%, and for example ±5%. As will be appreciated by the person of ordinary skill, the specific such deviation for a numerical value for a given technical effect will depend on the nature of the technical effect. For example, a natural or biological technical effect may generally have a larger such deviation than one for a man-made or engineering technical effect. As will be appreciated by the person of ordinary skill, the specific such deviation for a numerical value for a given technical effect will depend on the nature of the technical effect. For example, a natural or biological technical effect may generally have a larger such deviation than one for a man-made or engineering technical effect. Where an indefinite or definite article is used when referring to a singular noun, e.g. “a”, “an” or “the”, this includes a plural of that noun unless something else is specifically stated.

It is to be understood that application of the teachings of the present invention to a specific problem or environment, and the inclusion of variations of the present invention or additional features thereto (such as further aspects and embodiments), will be within the capabilities of one having ordinary skill in the art in light of the teachings contained herein.

Unless context dictates otherwise, the descriptions and definitions of the features set out above are not limited to any particular aspect or embodiment of the invention and apply equally to all aspects and embodiments which are described.

All references, patents, and publications cited herein are hereby incorporated by reference in their entirety.

In view of the above, it will be appreciated that the present invention also relates to the following itemised embodiments:

In a first item, the present invention relates to a functionalized electron microscopy (EM) support comprising at least one or more area(s) functionalized with at least one substrate allowing for the adhesion of biological specimen, particularly live (mammalian) cells, particularly live cells, or generally for the immobilization of macromolecules, such as biological macromolecules, for example antibodies, hormones, toxins, cytokines, etc., wherein the area(s) is/are at least partially, preferably completely, surrounded by at least one passivation layer substance, wherein said substance repels live cells and/or essentially does not allow for the adhesion of live cells. Alternatively, the passivation layer substance that prevents adhesion of live cells by at least 50% or more, for example by at least 60%, by at least 70%, by at least 80%, by at least 90% compared with areas that are functionalized with at least one or more substrate(s) allowing for the adhesion of biological specimen, particularly live cells. For the analysis of immobilized macromolecules the passivation layer substance has also the effect that the macromolecules that are analysed tend to be immobilized in the area(s) that have been treated to the passivation layer and that have been functionalized to immobilize the macromolecules referred to above. The ablation of the passivation layer substance is preferably made with a pulse-laser suitable for photo-micropatterning the support, e.g. an EM grid.

The invention hence relates to electron microscopy (EM) supports for in situ cryo-electron tomography, particularly to contactless and mask-free photo-micropatterning of EM grids for site-specific deposition of extracellular matrix-related proteins for micromachining by cryo-focused ion beam milling. The new EM supports allow for analysis of intracellular organization, permitting direct correlation of cell biology and biomechanics by 3D-structural characterization of the underlying molecular machinery in cellulo.

In further items, the biological specimen may be any biological macromolecule of interest that may be positioned in the micro-patterned area(s). Examples are proteins including antibodies, which may be of assistance in, for example, Single Particle Analysis (SPA). Micro-patterned areas can be modified chemically as long as this chemical component does not also bind to the passivation layer substance by at least 50% or more, for example by at least 60%, by at least 70%, by at least 80%, by at least 90% compared with areas that are functionalized with at least one or more substrate(s) allowing for the adhesion of biological specimen.

In a further embodiment, the functionalized EM support is based on an electron microscopy grid, for example a grid comprising or consisting of gold, copper, molybdenum, or titanium, optionally comprising a biocompatible layer, preferably a SiO2-, graphene-, carbon-, or gold-film, particularly a SiO2-film or a graphene-film. As used herein, a grid is a metal mesh (i.e., it looks like crossed bars) with a thin film on top in the whole grid. The film is usually patterned in the middle of a grid square.

In accordance with other embodiments of the invention, it is also possible to create a pattern on top of the grid bars. This permits using interacting partners (Streptavidin in the patterns and Biotin in the fiducials, or Antibody anti-GFP in patterns and GFP on fiducials) which can be directed to the regions of the film that are on top/above the grid bars, e.g., fiducials may be positioned on top of such bars, which is of major importance for correlation purposes between light and electron microscopy.

Therefore, in a further embodiment, the functionalized EM support further comprises fiducials, particularly, fluorescent beads specifically positioned on the EM support, particularly on top of grid bars, which may be used, for example, for the above-indicated purposes. A particularly preferred embodiment relates to micropatterning of fiducials, particularly, fluorescent beads to bars.

In a further embodiment, the functionalized EM support comprises a passivation layer substance that comprises or is a repelling agent, e.g. a biochemical or biophysical repelling agent. As used herein, repelling means that the biological specimen essentially do not bind to/adhere to the substance forming the passivation layer, or that the binding/adhesion is reduced by at least 50%, preferably more, as pointed out above. The passivation layer may be polyethylene glycol (PEG). Particularly, two different passivation examples are described in the following. In one approach, PLL-PEG may be used, where the PLL section binds to the surface and exposes the PEG chains forming initially coated layer that is subsequently ablated. In another approach a two-step passivation may be performed by first treating EM grids with PLL alone and subsequently with PEG-sva that binds covalently to PLL. It is also possible to use a bio-passivation agent such as protein or DNA that may be ablated with the laser, leaving few micro-patterned areas, where the biological agent is used as bio-passivation. Also, detergents, such as Tween, could be used to passivate surfaces, but they are not biocompatible, i.e. cells will not grow there. Such passivation can be useful in proteomic analysis, e.g. transmembrane proteins (reference is made to the above-mentioned Single Particle Analysis of biological macromolecules). In particular embodiments of the present invention, the tools and methods described herein pertain to the analysis of cells, e.g. mammalian cells, but cells from organisms other than mammals, or even microorganisms are also suitable for analysis using the herein described EM supports.

In further items of the present invention, the passivation layer substance forms a pattern comprising one or more microscopically distinguishable area(s) so that defined areas comprising the cells or macromolecules of interest can be distinguished. Microscopically distinguishable means that the respective areas may not always be distinguishable to the naked eye, but also that the areas may not be absolutely identical in shape and size. However, these areas should appear essentially homogenous and regular when viewed through a microscope.

In further items, the repelling agent comprises a polyether, polyethylene glycol, and/or PLL-g-PEG as explained in more details in the examples section.

In further items, the substrate for the adhesion of live cells comprises proteins, glycoproteins, and/or polysaccharides, particularly proteins are suitable as substrates for live cells. In embodiments of the invention, the substrate for the adhesion of live cells comprises at least one extracellular matrix component selected from the group comprising laminin, fibronectin, vitronectin, integrin, collagen, fibrillin, elastine, glycosaminoglycane and the like.

In further items, when biological macromolecules such as antibodies, etc. are analysed, the functionalization substrate may be adequately selected to ensure the specific binding to areas in the grid that are sufficiently distant from the passivation layer so that the molecules can be relatively easily distinguished and characterized.

In further items, the present invention relates to the functionalized electron microscopy (EM) support comprising at least one live cell or at least one fixed cell per one area. The cells may still be capable of cell division before fixation (vitrification) which may increase the number of cells per given area. In some embodiments, the cells may be selected from the group comprising stem cells, induced stem cells, pluripotent stem cells, primary cells, transformed cells, neuronal cells, blood cells, immune cells, cancer cells, genetically engineered cells, infected cells, and the like. In some embodiments, the cells are mammalian cells, wherein the term “mammalian” comprises any mammal, particularly humans. However, it is also possible to use cells that are not of mammalian origin, e.g., cells derived from insects, fish, birds, etc.

In still further embodiments, the present invention relates to a method of preparing the functionalized electron microscopy (EM) support according to any of the foregoing embodiments for specimen analysis, said method comprising:
a) Providing an EM support,
b) Coating said EM support with at least one passivation layer substance that essentially does not allow for the adhesion of live cells or acts a cell repellent, and
c) Photo-micropatterning said coated EM support.

In further items, the present invention relates to the method according to the preceding embodiment, wherein the photo-micropatterning step is a contactless and/or mask-free photo-micropatterning step.

In further items, the present invention relates to the method according to any one of the preceding items, the photo-micropatterning step removes or ablates the passivation layer substance of step b). Step b) may be preceded by a cleaning step, e.g. a plasma cleaning step in order to render the grids oxidized and hydrophilic before coating the same the passivation layer substance.

In further items, the present invention relates to the method according to preceding embodiments, wherein the photo-micropatterning step is performed with a UV-laser, particularly a 300 nm to 370 nm pulse laser, 310 nm to 370 nm pulse laser, 320 nm to 365 nm pulse laser, 330 nm to 360 nm pulse laser, particularly a 355 nm pulse laser. Alternatively, the photo-micropatterning step is performed by UV-illumination with a digital micro-mirror device (DMD). When using a laser at less than 300 nm or above 375, the ablation of the passivation layer does not function properly or, at less than 300 nm, cause stronger damage to the EM support.

In further items, the present invention relates to the method according to preceding embodiments, further comprising step d) comprising functionalizing the previously ablated (i.e. passivation layer-free) areas of the of the EM support with at least one substrate allowing for the adhesion of live cells in those areas where the photo-micropatterning step removed the passivation layer substance applied in step b). When the specimen subject to analysis is a biological macromolecule, the substrate may also be a chemical substrate allowing for the specific binding of the macromolecule to the functionalized are, wherein the macromolecule essentially does not bind or adhere to the passivation layer substance(s).

In further items, the present invention relates to the method according to preceding embodiments, wherein the passivation layer substance comprises or is a repelling agent. As indicated above, the passivation layer substance preferably forms a pattern of one or more microscopically distinguishable fields, particularly a grid-shaped pattern. The repelling agent may comprise a polyether, particularly polyethylene glycol.

In further items, the present invention relates to the method according to preceding embodiments, wherein the substrate for the adhesion of live cells comprises proteins, glycoproteins, polysaccharides, amongst other.

In further items, the present invention relates to the method according to preceding embodiments, further comprising at least one step d), wherein at least one live cell is seeded in at least one area functionalized with a substrate allowing for the adhesion of live cells. Alternatively, it is possible to functionalize the respective fields with a substrate that is specifically adapted to bind biological macromolecules.

In further items, the present invention relates to the method according to preceding items, wherein said method further comprises at least one step e), wherein at least one or more live cell(s) is/are fixed to the EM support, precisely to the substrate-functionalized areas.

In further item, the present invention relates to the method according to any of the preceding items, wherein said method comprises automated cryo-FIB milling.

In further embodiments, the present invention relates to the use of an EM-support as defined in any one of preceding embodiments or of an EM-support prepared in a method according to any one the above embodiments in the (e.g. structural and biophysical, biomechanical) analysis of adherent cells (for example, cell shape, cytoskeletal architecture, stereotypical internal organization of cellular organelles, etc.), particularly comprising at least one method selected from the group comprising microscopy, confocal microscopy, vitrification, cryo-FIB milling, transmission electron microscopy, cryo-light microscopy, cryo-electron tomography, cryo-focused ion beam (FIB) analysis, cryo-correlative light-electron microscopy (Cryo-CLEM), and/or cellular micromachining by cryo-FIB milling.

Yet another aspect of this invention, which can be combined with any other aspect and/or embodiment of this invention, pertains to a method for producing a circuit of cells, comprising the steps of:
a) Providing a functionalized electron microscopy support according to this invention, or a functionalized electron microscopy support prepared in a method according to this invention,
b) Providing at least two cells, and
c) Seeding said cells in at least one area of said electron microscopy support functionalized with a substrate allowing for the adhesion of said cells,
   thereby generating the circuit of cells on the electron microscopy support.

According to this invention, the term “a circuit of cells” shall refer to any device capable of holding at least two cell types, such as a chip, wherein said device comprises at least two cells growing in form of a micropatterned-based circuit, for example in form of a micropatterned-based circuit on a grid.

Another specific embodiment of this invention relates to the method for producing a circuit of cells, wherein the cells are selected from neurons, hepatocytes, myocytes, cardiomyocytes, stem cells, stem cell progenitor cells, trophoblasts, astrocytes, glial cells, enterocytes, hepatic cells, kidney cells, endothelial cells, epithelial cells, such as biliary epithelial cells, syncytiotrophoblasts, cytotrophoblasts, mesenchymal cells, inner cochlea cells, outer cochlea cells, trophoblasts, preferably wherein the cells are human cells, such as human neurons.

A further preferred embodiment of this invention relates to the method for producing a circuit of cells, wherein said cells belong to the same cell type or to at least two different cell types. Preferably, the method for producing a circuit of cells is used to generate a circuit of cells belonging to the same cell type or belonging to different cell types. The latter can, for example, be a circuit comprising different brain cells, such as neurons, astrocytes and glial cells.

A further specific embodiment of this invention relates to a method for producing a circuit of cells, further comprising the step of:
d) analysis of biomolecules or of adherent cells, particularly comprising at least one method selected from the group comprising microscopy, confocal microscopy, vitrification, cryo-FIB milling, transmission electron microscopy, cryo-light microscopy, cryo-electron tomography, cryo-focused ion beam (FIB) analysis, cryo-correlative light-electron microscopy (Cryo-CLEM), and/or cellular micromachining by cryo-FIB milling.

Yet another aspect of this invention, which can be combined with any other aspect and/or embodiment of this invention, pertains to a circuit of cells produced by the method for producing a circuit of cells of the specific aspect and embodiments above.

A further aspect of this invention relates to a circuit of cells produced by the method for producing a circuit of cells of this invention for use in medicine.

Yet another aspect of this invention, which can be combined with any other aspect and/or embodiment of this invention, pertains to a circuit of cells produced by the method for producing a circuit of cells for use in the treatment and/or prevention of a brain disease, spinal-cord injury, a heart disease, liver failure, kidney failure, deafness, a degenerative disease, such as a neurodegenerative disease, and/or a skin disease, or in the manufacture of a medicament against a brain disease, spinal-cord injury, a heart disease, liver failure, kidney failure, deafness, a degenerative disease, such as a neurodegenerative disease, and/or a skin disease.

Another aspect of this invention relates to a circuit of cells produced by the method for producing a circuit of cells of this invention to repair at least one damaged circuit in or on the human body, for example to repair a damaged neuronal circuit. According to this aspect of the invention, said circuit of cells produced by the method for producing a circuit of cells can be used as an implant or as a pacemaker, preferably as an organ implant, such as a brain implant, a cochlea implant, or a liver implant.

Yet another aspect of this invention pertains to a method of treatment and/or prevention of a brain disease, spinal-cord injury, a heart disease, liver failure, kidney failure, deafness, a degenerative disease, such as a neurodegenerative disease, and/or a skin disease in a subject, the method comprising the step of administering to the subject a circuit of cells produced by the method for producing a circuit of cells of this invention.

A further preferred embodiment of this invention relates to the method of treatment and/or prevention, wherein said subject is a mammal, such as a human, a mouse, rat, guinea pig, rabbit, cat, dog, monkey, preferably a human, for example a human patient, more preferably a human patient suffering from a brain disease, spinal-cord injury, a heart disease, liver failure, kidney failure, deafness, a degenerative disease, such as a neurodegenerative disease, and/or a skin disease.

Yet another aspect of this invention pertains to the use of a functionalized electron microscopy support defined in any one of preceding embodiments or of a functionalized electron microscopy support prepared in a method according to any one the preceding embodiments for generation of a circuit of cells on the electron microscopy support.

A further aspect of this invention pertains to the use of a functionalized electron microscopy support defined in any one of preceding embodiments or of a functionalized electron microscopy support prepared in a method according to any one the preceding embodiments as a neuronal microprocessor for computing, information processing and storage.

Additional items of the present invention:
Item 1: A functionalized electron microscopy support comprising at least one or several area(s) functionalized with a substrate allowing for the adhesion of a biological specimen, particularly a living cell,
   wherein the functionalized area(s) is/are at least partially or is completely surrounded by at least passivation layer substance, wherein said substance at least partially repels live cells and/or does not allow for, or at least partially reduces the adhesion of live cells.
Item 2: The functionalized electron microscopy support according to item 1, wherein the electron microscopy support is an electron microscopy grid, particularly comprising or consisting of gold, copper, molybdenum, titanium or platinum.
Item 3: The functionalized electron microscopy support according to items 1 or 2, wherein said electron microscopy support optionally comprises a biocompatible film, preferably a SiO2-, graphene, carbon-, gold-film, or silicon nitride (Si₃N₄), particularly a SiO2-film.
Item 4: The functionalized electron microscopy support according to any one of items 1 to 3, wherein the support further comprises fiducials, particularly fluorescent beads specifically positioned on the support.
Item 5: The functionalized electron microscopy support according to any one of items 1 to 4, wherein the passivation layer substance comprises is a repelling agent.
Item 6: The functionalized electron microscopy support according to any one of items 1 to 5, wherein the repelling agent comprises a polyether, polyethylene glycol, and/or PLL-g-PEG.
Item 7: The functionalized electron microscopy support according to any one of items 1 to 6, wherein the passivation layer substance forms a pattern comprising one or more microscopically distinguishable area(s).
Item 8: The functionalized electron microscopy support according to any one of items 1 to 7, wherein the substrate for the adhesion of live cells comprises proteins, glycoproteins, and/or polysaccharides.
Item 9: The functionalized electron microscopy support according to any one of items 1 to 8, wherein the substrate for the adhesion of live cells comprises at least one extracellular matrix component selected from the group comprising laminin, fibronectin, vitronectin, integrin, collagen, fibrillin, elastine, and glycosaminoglycane, RGD peptides, and RGD-conjugated chemicals or proteins.
Item 10: The functionalized electron microscopy support according to any one of items 1 to 9, further comprising at least one living cell or fixed cell in at least one area.
Item 11: A method of preparing the functionalized electron microscopy support as defined in any one of items 1 to 10, said method comprising:
   a) Providing an electron microscopy support,
   b) Coating said electron microscopy support with a passivation layer substance, particularly wherein said substance at least partially repels live cells and/or does not allow for, or at least partially reduces the adhesion of live cells,
   c) Photo-micropatterning said coated electron microscopy support obtained in b).
Item 12: The method according to item 11, wherein the photo-micropatterning step is a contactless and/or mask-free photo-micropatterning step.
Item 13: The method according to items 11 or 12, wherein the photo-micropatterning step locally removes the passivation layer substance of step b) to provide areas which are essentially free of passivation layer substances.
Item 14: The method according to any one of items 11 to 13, wherein the photo-micropatterning step is performed with a pulse laser, particularly with a 300 nm to 70 nm pulse laser, more particularly with a 355 nm pulse laser, or said step is performed by UV-illumination with a digital micro-mirror device (DMD).
Item 15: The method according to any one of items 11 to 14, further comprising a step d) comprising functionalizing with substrate allowing for the adhesion of live cells in those areas where the photo-micropatterning step removed the passivation layer substance applied in step b).
Item 16: The method according to any one of items 11 to 15, wherein the passivation layer substance comprises a repelling agent.
Item 17: The method according to any one of items 11 to 16, wherein the repelling agent comprises a polyether, particularly polyethylene glycol or PLL-g-PEG.
Item 18: The method according to any one of items 11 to 17, said method further comprising step e), wherein at least one living cell is seeded in at least one area functionalized with a substrate allowing for the adhesion of live cells.
Item 19: The method according to any one of items 11 to 18, wherein the substrate for the adhesion of live cells comprises proteins, glycoproteins, polysaccharides.
Item 20: The method according to any one of items 11 to 19, said method further comprising step e), wherein the living cell is fixed or vitrified to the support.
Item 21: The method according to any one of items 11 to 20, wherein said method further comprises automated cryo-FIB milling.
Item 22: Use of functionalized electron microscopy support as defined in any one of items 1 to 10, or of an functionalized electron microscopy support prepared in a method according to any one of items 11 to 20 in the analysis of biomolecules or of adherent cells, particularly comprising at least one method selected from the group comprising microscopy, confocal microscopy, vitrification, cryo-FIB milling, transmission electron microscopy, cryo-light microscopy, cryo-electron tomography, cryo-focused ion beam (FIB) analysis, cryo-correlative light-electron microscopy (Cryo-CLEM), and/or cellular micromachining by cryo-FIB milling.
Item 23: A method for producing a circuit of cells, comprising the steps of:
   a) Providing a functionalized electron microscopy support according to any one of items 1 to 10, or a functionalized electron microscopy support prepared in a method according to any one of items 11 to 20,
   b) Providing at least two cells, and
   c) Seeding said cells in at least one area of said electron microscopy support functionalized with a substrate allowing for the adhesion of said cells,
   thereby generating the circuit of cells on the electron microscopy support.
Item 24: The method according to item 23, wherein the cells are selected from neurons, hepatocytes, myocytes, cardiomyocytes, stem cells, stem cell progenitor cells, trophoblasts, astrocytes, glial cells, enterocytes, hepatic cells, kidney cells, endothelial cells, epithelial cells, such as biliary epithelial cells, syncytiotrophoblasts, cytotrophoblasts, mesenchymal cells, inner cochlea cells, outer cochlea cells, trophoblasts, preferably wherein the cells are human cells, such as human neurons.
Item 25: The method according to item 23 or 24, wherein said cells belong to the same cell type or to at least two different cell types.
Item 26: A circuit of cells produced by a method according to any one of items 23 to 25.
Item 27: A circuit of cells according to item 26 for use in medicine.
Item 28: A circuit of cells according to item 26 for use in the treatment and/or prevention of a brain disease, spinal-cord injury, a heart disease, liver failure, kidney failure, deafness, a degenerative disease, such as a neurodegenerative disease, and/or a skin disease, or in the manufacture of a medicament against a brain disease, spinal-cord injury, a heart disease, liver failure, kidney failure, deafness, a degenerative disease, such as a neurodegenerative disease, and/or a skin disease.
Item 29: Use of a circuit of cells according to item 26 to repair at least one damaged circuit in or on the human body, for example to repair a damaged neuronal circuit.
Item 30: Use of a circuit of cells according to item 26 as an implant or as a pacemaker, preferably as an organ implant, such as a brain implant, a cochlea implant, or a liver implant.
Item 31: A method of treatment and/or prevention of a brain disease, spinal-cord injury, a heart disease, liver failure, kidney failure, deafness, a degenerative disease, such as a neurodegenerative disease, and/or a skin disease in a subject, the method comprising the step of administering to the subject a circuit of cells according to item 26.
Item 32: The method according to item 31, wherein said subject is a mammal, such as a human, a mouse, rat, guinea pig, rabbit, cat, dog, monkey, preferably a human, for example a human patient, more preferably a human patient suffering from a brain disease, spinal-cord injury, a heart disease, liver failure, kidney failure, deafness, a degenerative disease, such as a neurodegenerative disease, and/or a skin disease.
Item 33: Use of a functionalized electron microscopy support defined in any one of preceding embodiments or of a functionalized electron microscopy support prepared in a method according to any one the preceding embodiments for generation of a circuit of cells on the electron microscopy support.
Item 34: Use of a functionalized electron microscopy support defined in any one of preceding embodiments or of a functionalized electron microscopy support prepared in a method according to any one the preceding embodiments as a neuronal microprocessor for computing, information processing and storage.

Other embodiments will become apparent to the person skilled in the art in light of examples infra.

### DESCRIPTION OF THE FIGURES

FIG. 1: Micropatterning of cryo-EM grids refines preparation for cryo-FIB lamella micromachining from adherent mammalian cells. (a) Standard gold-mesh grid with SiO2 (R2/1) holey film. Cyan circle indicates grid center. Only a small fraction of HeLa cells are optimally positioned for FIB-lamellae preparation (arrowheads). (b) Gold-mesh holey grid with 20 μm diameter disks patterns on 8×8 grid squares around the grid center (cyan circle) treated with fibronectin. (c-d) HeLa cells, stably expressing both GFP tagged β-tubulin (Cyan) and mCherry tagged histone (H2B-mCherry: magenta), seeded on a (c) control and (d) patterned gold-mesh grids with SiO2 (R1/20) holey film (inset in d: H-shaped pattern induced the square cell shape. Scale: 20 μm). Cell-cycle was synchronized with a single Thymidine block (16 h), released into fresh medium with overnight live cell imaging. A field of view of a single grid square is shown for both (c) and (d). Cells continue dividing ˜40 h post-seeding. (e) FIB shallow angle view on cell framed in (b). Yellow rectangles indicate patterns for milling. (f) Final lamella produced from cell in (e). (g) Tomographic slice, 6.8 nm thickness, of the nuclear periphery of the cell in (e). Lamella thickness determined from the tomographic reconstruction was 90 nm. NPC: nuclear pore complex; MT: microtubule.

FIG. 2: Cryo-EM grid micropatterning tailored for controlling cellular morphology and cytoskeletal architecture. On-grid live-cell confocal microscopy of the actin organization in RPE LifeAct-GFP cells grown on complex micropatterns (gold-mesh, SiO2 film R1/4). Positioning of actin stress fibers (yellow arrowheads) correlate with the distinct patterns. Blue arrowhead: actin rings composed of putative bundles. (b-f) Cellular cryo-ET of RPE cells in peripheral thin regions. (b) Cryo-TEM map of grid with 8×7 patterned grid squares (gold-mesh, SiO2 film R1/4). Patterns per row are indicated (left column). Cyan circle: grid center. Framed cell is enlarged in (c). (c) Cryo-TEM micrograph of a grid square of the indicated cell in (b) grown on a cross-shaped pattern (rotated 90° counter-clockwise from b). (d) Magnified cryo-TEM micrograph of the framed area in (c) (rotated 90° clockwise from c), targeted for tomography. (e) Tomographic slice of the specified area in (d), 6.8 nm thickness, showing the organization of actin filaments into a stress fiber and an isotropic meshwork in the adjacent lamellipodium. (f) Tomographic slice of the periphery of another cell grown on an oval-shape pattern depicting actin meshwork, bundles, and unidentified hexameric macromolecular complexes at the basal and epical cell membranes (inset arrowhead). (g-m) Cellular thinning by cryo-FIB followed by cryo-ET. (g) SEM of RPE cells on a patterned titanium-mesh holey (SiO2 film R1/20) grid and overlaid with an image of the patterns. Bottom left: 2 keV SEM image of a cross-shaped micropatterned grid square. Right: SEM of RPE cell spreading on a cross-shaped pattern. (h) SEM of a cell grown on a crossbow-shaped pattern (yellow) overlaid with the SEM micrograph of a wedge (top view) produced by cryo-FIB milling. Yellow squares indicate the positions of tomographic slices in (j) and (k). (i) Upper panel: FIB shallow angle view on cell in (h). Yellow rectangle indicates the pattern for milling. A thin wedge at the basal cell membrane is produced by ablating the top of the cell. Lower panel: cell after milling. (j-k) Tomographic slices of the positions 1 and 2 indicated in (h). Actin bundles likely equivalent to actin transverse arcs (parallel to but distant from cell edge) and internal stress fibers—indicated in (a)—are found in locations expected according to the actin map in a crossbow-shaped RPE1 cell.

FIG. 3: (a) Grid passivation with anti-fouling agent PLL-g-PEG generates an organized repulsive PEG brush at the surface. (b) UV laser application using a 355 nm pulsing laser scanned through the region of interest causes ablation of the passivation layer. (b′) UV laser application using a digital-micromirror device and the photo-initiator PLPP to locally oxidize the passivation layer. (c) Spatially constrained ablation of the PLL-g-PEG passivation layer. (d) Grid functionalization with extracellular matrix (ECM)-related proteins. (e) Cell seeding at the functionalized micropatterned areas.

FIG. 4: Photo-micropatterning of EM grids using a UV-355 nm pulsing laser. (a-b) Light microscopy imaging of micropatterns generated by a 355 nm wavelength pulsing laser scanned to generate a 30 μm disk-shaped area (gold-mesh grid, SiO2 film R1/4). The micropatterned area can be identified by the impression left as a result of laser pulses on the SiO2 film. (c-d) Cryo-FIB/SEM imaging of a micropatterned grid post-vitrification displaying the engraving made by the laser. (e) Gold-mesh holey grid micropatterned 4×4 grid squares (30 μm disk-shape) around the grid center (cyan circle), treated with fibronectin and seeded with HeLa cells. Cells are constrained to the patterned area. (f) Light microscopy imaging of a grid 2.5 h after seeding (upper-panel), displaying single cells at the micropatterned circular region. Cell division (24 h post-seeding, lower-panel) is restricted to the micropatterned area. (g) FIB shallow angle view of a cell grown on a disk-shaped pattern under cryogenic conditions. Yellow rectangles indicate the pattern for milling to produce a thin and central lamella through the cell. (h) FIB view of the cell after milling to generate a ˜200 nm thin lamella. (i-j) SEM top views of the lamella from (h).

FIG. 5: Micropatterning of graphene monoatomic layer. (a) A graphene monoatomic layer (3.4 Å—single atom thickness) was overlaid on a grid (gold 200 mesh, carbon film, R2/1: 2 μm holes spaced by 1 μm). Following the procedure, an area of 6×6 grid squares (yellow dashed line) was micropatterned with a 30 μm disks after passivation. The patterns were coated with green fluorescent protein (GFP) for visualization. Blue circle: grid center. (b) Grid square indicated in (a) (red square area). Inset: zoom of the area indicated by the yellow dash line. In both micrographs, it can be observed that the fluorescent protein is visible across the (2 μm) holes of the grid, therefore, adhering to the micropatterned graphene monolayer. (c) Correlative scanning electron microscopy (SEM) micrograph of the grid shown in (a), depicting the micropatterned area (yellow dashed area) and grid center (blue circle). (d) High-voltage (30 keV) SEM image of the grid square from (b) (also indicated in (a) and (c)—red square area). (e) High-voltage (30 keV) SEM image of the micropatterned area (green disk) from (b) equivalent to the central area of the image in (d). The yellow arrowheads indicate a translucent film in holes. (f) Correlative transmission electron microscopy (TEM) micrograph of the grid square shown in (d). Yellow dashed circle indicates the micropatterned area. (g). Fourier transform of a TEM micrograph from a 2 μm hole within the micropatterned area shown in F. The 2D power spectrum displays a hexagonal diffraction pattern with a periodicity of ˜2.11 Å (indicated in red circles) typical for pristine graphene. The indicated Debye-Scherrer ring represent the scattering of amorphous ice.

FIG. 6: Micropatterning of graphene oxide and cell seeding. Graphene oxide was deposited on a gold grid (200 mesh, SiO₂ film, R1/4: 1 μm holes spaced by 4 μm). In this procedure multiple layers (e.g., 3 layers with a thickness of ˜1 nm) of graphene oxide can be deposited. Micropatterning was performed suing the indicated area and placing a 20 μm disk at the center of each grid square. These disks were coated with fibronectin. After the seeding, RPE-1 cells were observed at micropatterned areas (yellow circle) as indicated by the yellow arrowheads.

FIG. 7: Cell positioning in patterned grids preparations. Gold-mesh holey (SiO2 film) grid with micropatterned 8×7 grid squares (H-shape of 30 μm size) around the grid center (cyan circle), treated with fibronectin, seeded with HeLa cells and imaged at 24 h post-seeding. Pattern design is overlaid.

FIG. 8: Correlation of grid maps from fluorescence and transmission electron microscopy. (a) On-grid live-cell imaging (confocal microscopy) to generate a grid map of RPE LifeAct-GFP culture (4 h post-seeding) on gold-mesh holey (SiO2 film R1/4) grid with 8×7 patterned grid squares. Micrograph is a maximum intensity projection of a z-stack. (b) Fluorescence microscopy map from (a) overlaid with the pattern design. The micrograph is contrast adjusted for better visualization. (c) Cryo-TEM map of same grid (vitrified ˜1 h after live-cell imaging), and overlaid with the fluorescence microscopy map. Cyan circle: grid center. Micrographs are flipped relative to FIG. 2b.

FIG. 9: Direct cryo-ET assessment of actin networks in cells grown on various micropattern shapes (FIG. 2b and FIG. 8). (a) Cryo-TEM micrograph of the grid square from FIG. 2c (grown on a cross-shaped pattern). Yellow lines indicate the expected positioning of peripheral stress fibers. (b) Cryo-TEM micrograph of the framed area in (a) (rotated 90° clockwise), displaying a stress fiber targeted for tomography. (c-d) Tomographic slices (6.8 nm thickness) through the 3D volume of the specified area in (b), showing the organization of actin filaments into a stress fiber. (e) Cryo-TEM micrograph of a different RPE cell grown on a cross-shaped pattern. (f) Cryo-TEM micrograph of the framed area in (e) (rotated 90° clockwise), displaying a lamellipodium with intricate actin architecture. (g-h) Tomographic slices (6.8 nm thickness) through the 3D volume of the specified area in (f), showing the organization of actin filaments into multiple interrelated bundles. (i) Cryo-TEM micrograph of a RPE cell grown on an oval-shaped pattern. (j) Cryo-TEM micrograph of the framed area in (i) (rotated 90° clockwise), displaying the targeted area. (k) Tomographic slice (6.8 nm thickness) of the periphery of the cell depicting actin filaments bundling. (l) Cryo-TEM micrograph of a RPE cell form FIG. 2f, which was grown on an oval-shaped pattern. (m) Cryo-TEM micrograph of the framed area in (l), displaying the targeted area represented in FIG. 2f.

FIG. 10: Actin networks architecture in RPE LifeAct-GFP cells grown on crossbow pattern. (a) On-grid live-cell Airyscan confocal slice at the basal part of an RPE cell (shown in FIG. 2a, top right) grown on a crossbow fibronectin-coated micropattern, and overlaid with the pattern design (yellow). (b) Actin network organization throughout the whole cell correlates with physical cues provided by cell-shape restriction to the micropattern shape: (i—top) an extended actin meshwork in the cellular periphery forms a lamellipodium in adhesive regions of the pattern. This network extends towards the inner part of the cell with perpendicular and parallel arcs of filament bundles (ii). (iii) Stress fibers connect regions of the cell positioned on non-adhesive passivated areas of the support. (d-f) Correlation of the cryo-ET data acquired on analyzed regions of the wedge from FIG. 2h. (d-e) Same figure as of FIG. 2h for correlation purposes. (e) Highlights the edge of the wedge on the original micromachined cell. (f) Representative actin map of a RPE cell on a crossbow micropattern overlapped with the location of the wedge edge and tomograms positioning. (g) Schematic representation of the actin architecture was well as organelles positioning of RPE cells spread on a crossbow-shaped micropattern. Models are not to scale.

FIG. 11: Micropatterning of grid bars and positioning of fiducials. (a) Fluorescent microscopy image of a grid (Au 200 mesh, SiO2, R1/4) micropatterned along the bars (3 μm thick lines at the center of the bars) and a disk of 20 82 m diameter at the center of the grid square, the latter used as control. The fiducials (fluorescent green beads of 2 μm) can be observed on top of the micropatterned areas (bar lines and disks). This technique provides sufficient fiducials at the grid bars in order to perform the alignment of images between the light microscope and the scanning electron microscope in cryogenic mode. Beads were functionalized with biotin group, and the bars were coated with Neutravidin. (b) Zoom of a section from image in panel (a). The yellow circle indicates the micropatterned area in the grid square, and the yellow arrowhead indicates a single fiducial at the grid bar. (c) Section of a grid (Au 200 mesh, SiO2, R1/20: 1 μm holes spaced by 20 μm) micropatterned along the bars (10 μm thick lines at the center of the bars) and a disk of 20 μm diameter at the center of the grid square. Beads (1 μm in size) were functionalized with PLL g PEG-Biotin, and the bars were coated with Neutravidin.

FIG. 12: Human neural network. (a-b) Scheme of the micropatterned circuit including 3 μm tick lines and 25 μm disks. (a) includes straight and curly lines, while (b) additionally includes a bypass and straight lines with a kink. The micropattern was coated with laminin protein for human neuron adherence, and covers a total area of 10×9 grid squares of the grid (Au 200 mesh, SiO2, R1/4) equivalent to ˜1.4 mm². (c-d) Grids seeded with induced human stem cells and differentiated to neurons (day-6 post seeding) on a grid with (c) a circuit depicted in (a), and (d) with the circuit depicted in (b). Human neurons can be observed in by fluorescence microscopy due to a soluble protein (Ngn2-GFP) spread across the cells. Neurons are observed following the micropatterned circuit. (e-g) Light microscopy image of a neuron (day-6 post seeding) growing on a micropattern with (e) strong curvature corresponding to the curly lines of the circuit, (f) a neuron challenged by the bypass area of a circuit, and (g) a neuron changing direction at the center (disk micropatterned area) of a grid square, and extending for about 5 grid squares displaying the growth ability of the neurons and the circuit capacity to guide them.

### EXAMPLES

Certain aspects and embodiments of the invention will now be illustrated by way of example and with reference to the description, figures and tables set out herein. Such examples of the methods, uses and other aspects of the present invention are representative only, and should not be taken to limit the scope of the present invention to only such representative examples.

### Example 1: Micropatterning of Functionalized Electron Microscopy Support

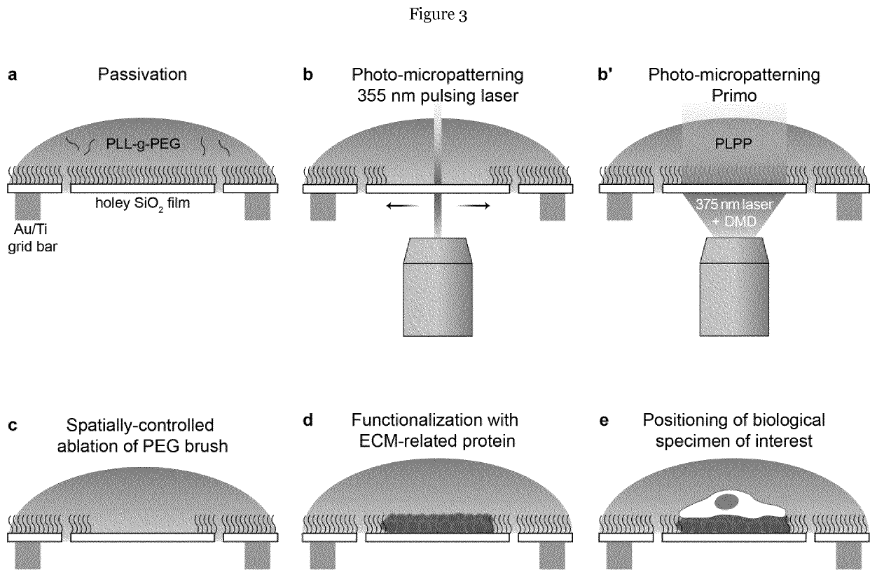

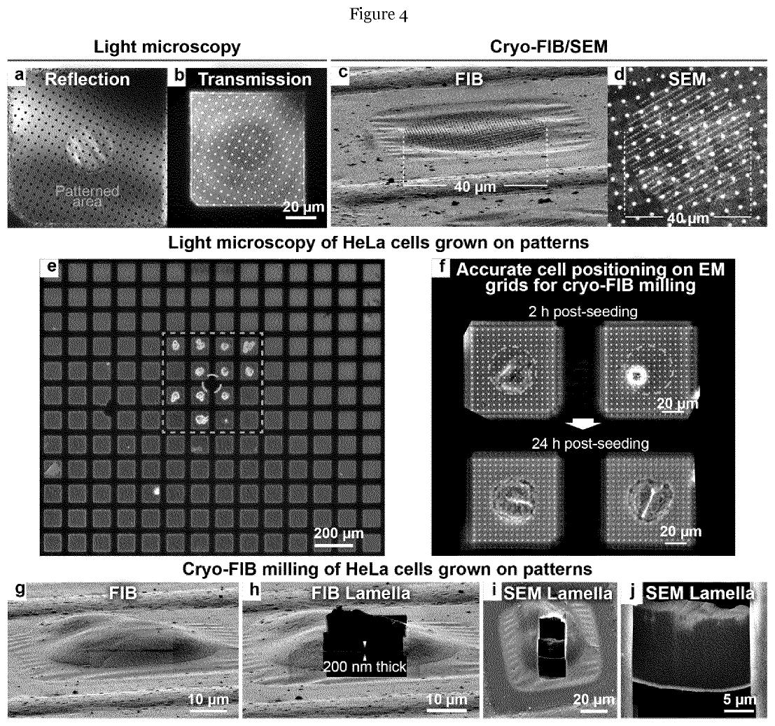

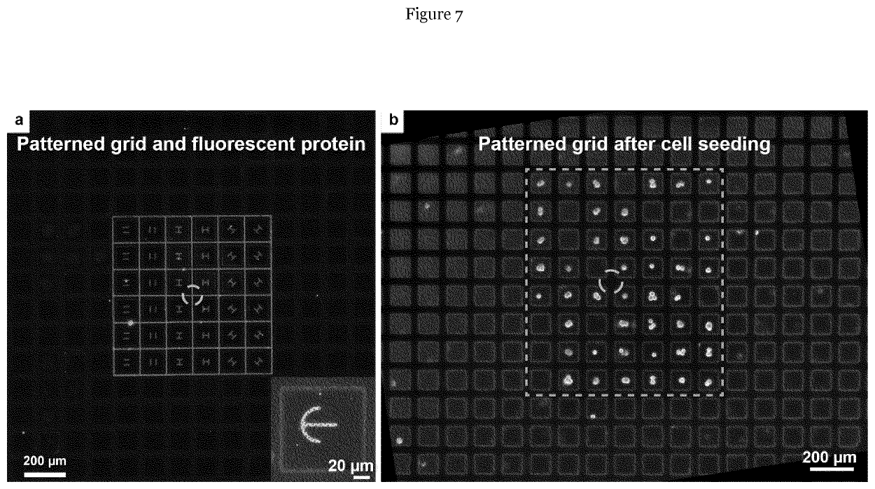

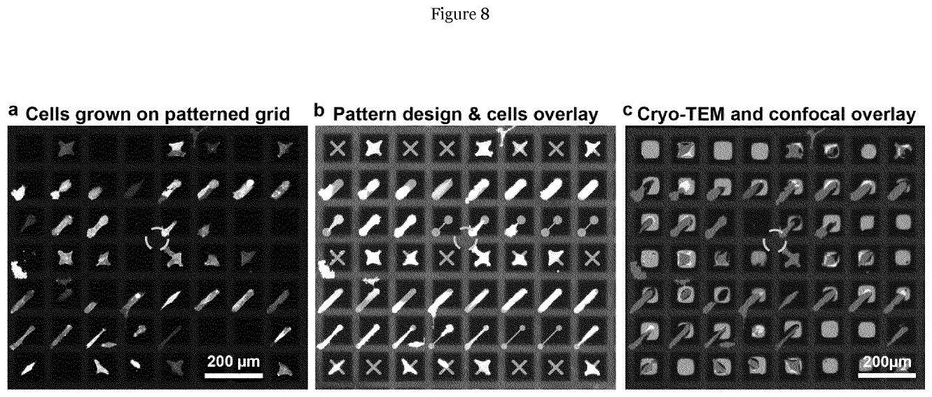

In order to perform the present invention contactless and mask-free photo-micropatterning were adapted (FIG. 3), ensuring preservation of the delicate support film and precise pattern generation within each grid square. The grids were plasma cleaned, rendering them hydrophilic, and coated with an anti-fouling biologically repelling agent (Polyethylene Glycol (PEG)-brush). Successively, specific areas were ablated with a UV-laser, either using a UV-pulsing laser scanned through the grid film on a standard confocal microscope (FIG. 4a-d) or continuous UV-illumination with a digital micro-mirror device (DMD) and a photo-activator (PLPP) 10 (FIG. 3). The DMD provides efficient area coverage of the grid film of approximately 150,000 micrometers (μm²), equivalent to about 3×2 grid squares on a 200-mesh grid, and allows creating multiple, complex, and precisely positioned PEG-free areas in ˜30 s at a resolution of 1.5 micrometers (μm²). The total patterned area can be extended by iterative montages of DMD expositions (FIG. 7). Following passivation and patterning, grids can be stored up to 30 days under hydrated conditions at 4° C. Grids were then functionalized with proteins that facilitated cell adhesion, and can be tailored to support growth and differentiation of various cell types, e.g. laminin for induced pluripotent stem cells-derived neurons.

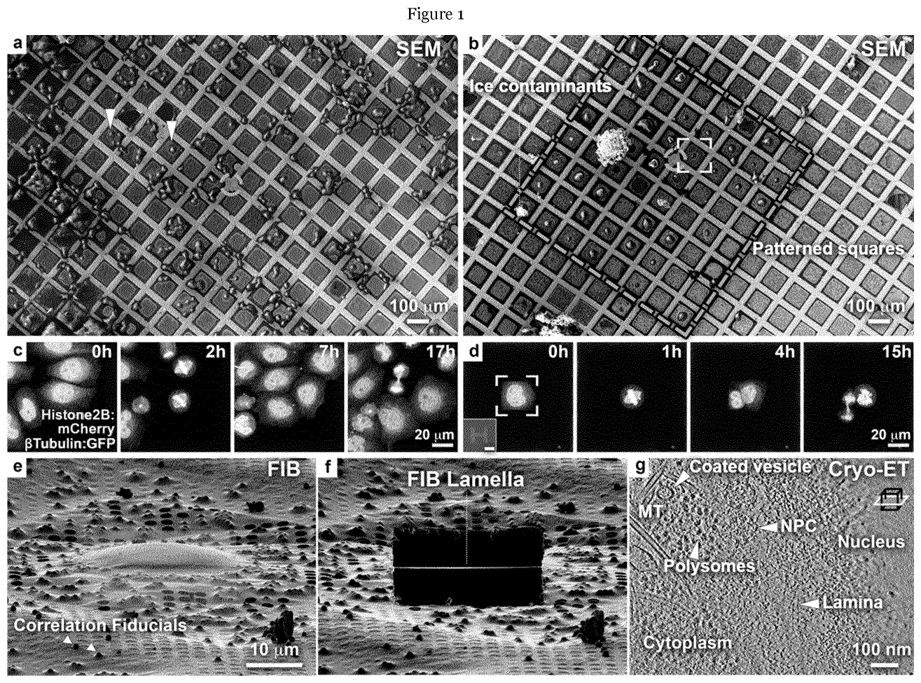

HeLa cells are a prominent model system in cell biology, and must be thinned to reveal structures positioned deep in their interior by cryo-ET. We seeded HeLa cells on fibronectin-functionalized micropatterned (30 μm disk-shape) grids. A reproducible seeding of single or double cells at the center of individual grid squares was achieved (FIG. 1b, FIG. 4e-g, FIG. 7). Cells viability on micropatterned grids was confirmed by live-cell imaging: time-lapse light microscopy of cell-cycle synchronized cultures showed that cells spread and continue to divide 40 h post-seeding (FIG. 1c-d). In this case, an H-shape pattern induced cells to adopt a rectangular appearance and can potentially be employed to produce defined geometries of cell division and the mitotic spindle for structural analysis^{Refs. 11,12}. The majority of cells seeded on such grids are directly accessible for FIB thinning (FIG. 1b, e), highlighting the potential of grid micropatterning in streamlining challenging thinning techniques. Next, electron-transparent lamellae were generated (FIG. 1f)^{Ref. 5,} and cryo-ET on the lamella produced 3D-tomographic volumes of the nuclear periphery capturing previously-described molecular detail^{Ref. 4} (FIG. ig). Thus, the developed EM grid micropatterning method contributes to optimization of advanced cellular cryo-ET pipeline, which encompasses (i) vitrification, (ii) cryo-correlative light microscopy, (iii) micromachining by cryo-FIB milling, and (iv) cryo-ET.

Next, complex patterns to control cell shape were generated. Micropatterning on glass surfaces has been previously shown to induce well-defined cytoskeletal architectures and, as a result, a stereotypical internal organization of cellular organelles^{Refs. 8,9}.

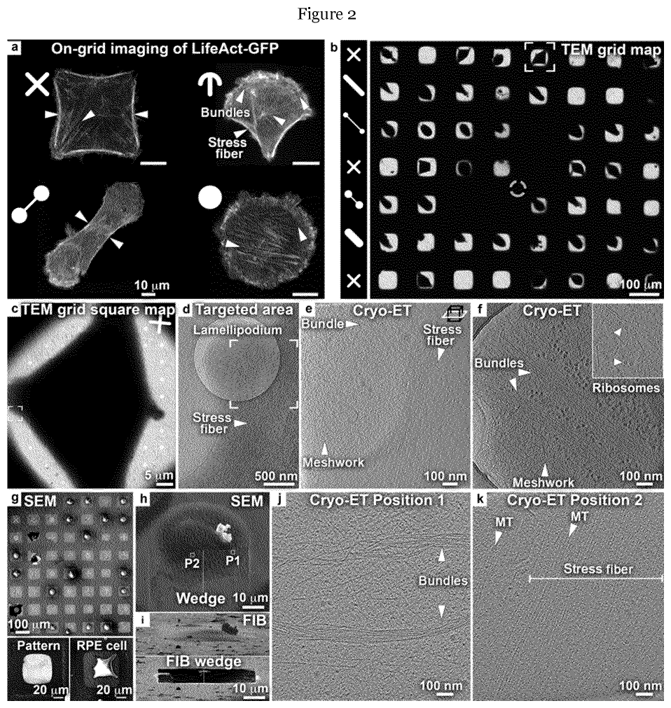

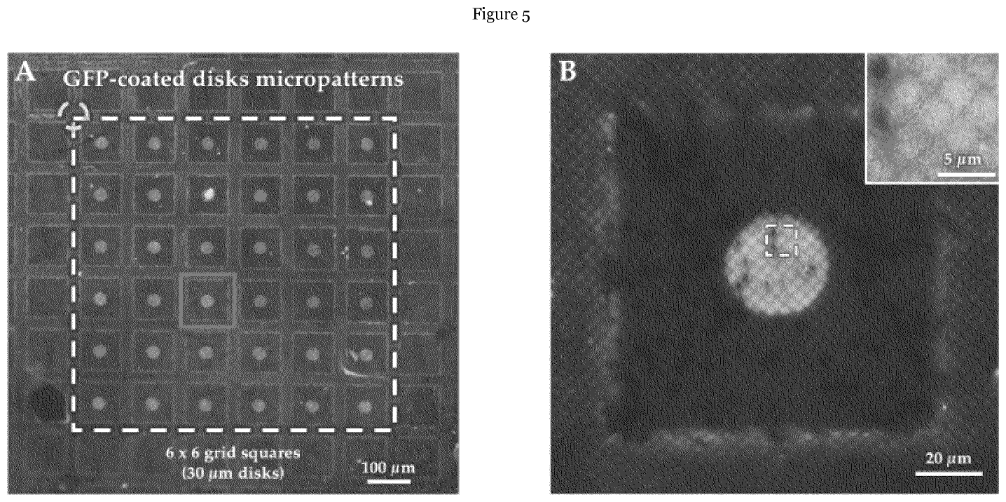

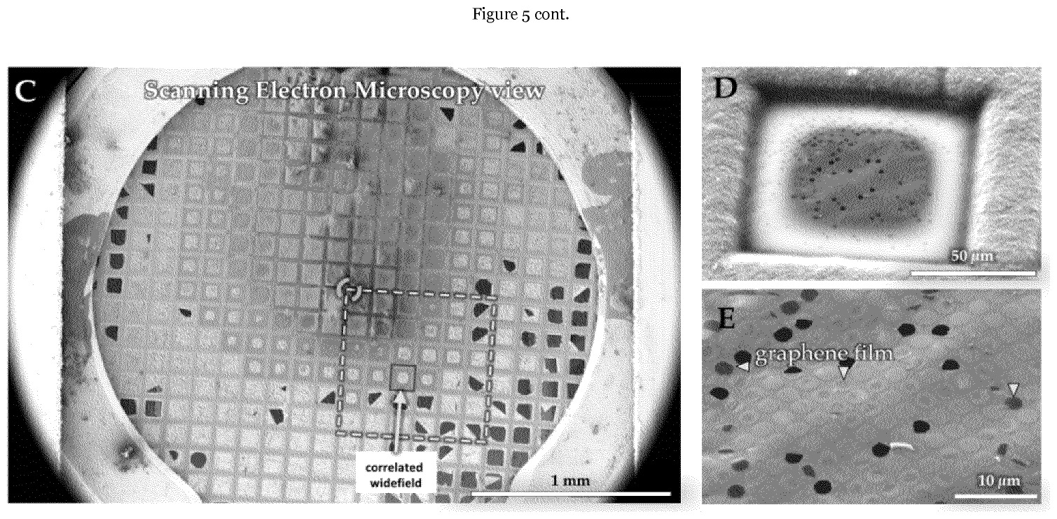

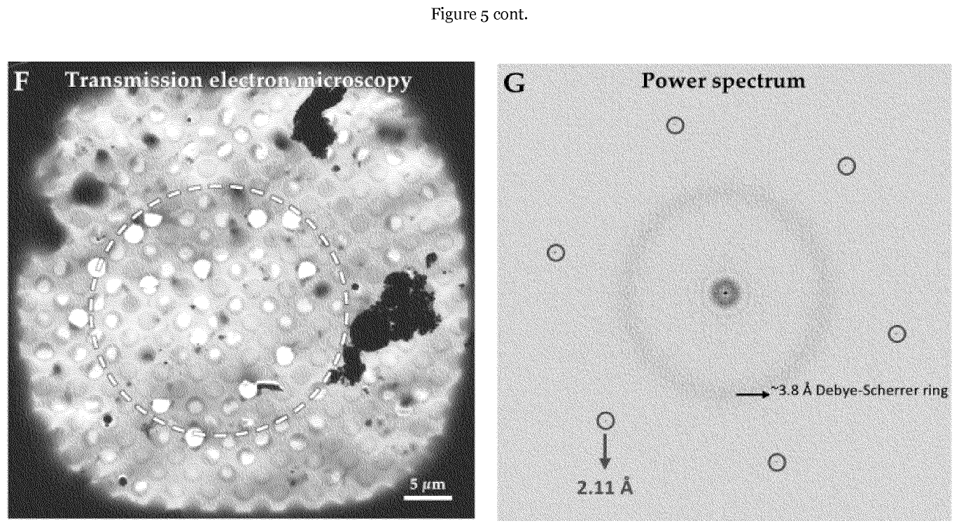

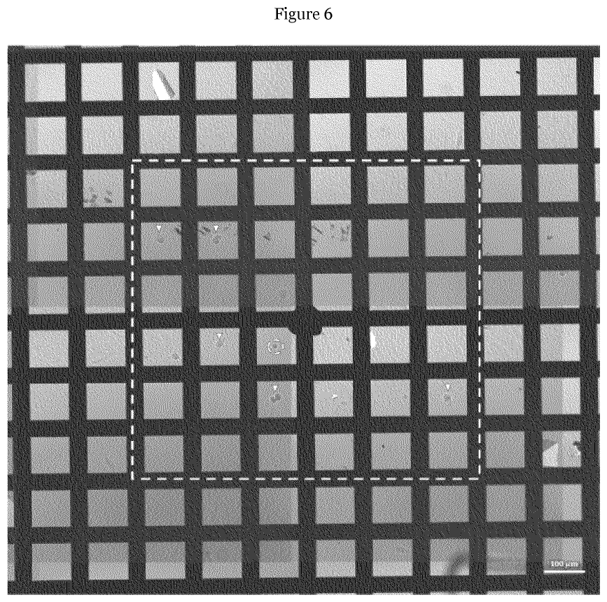

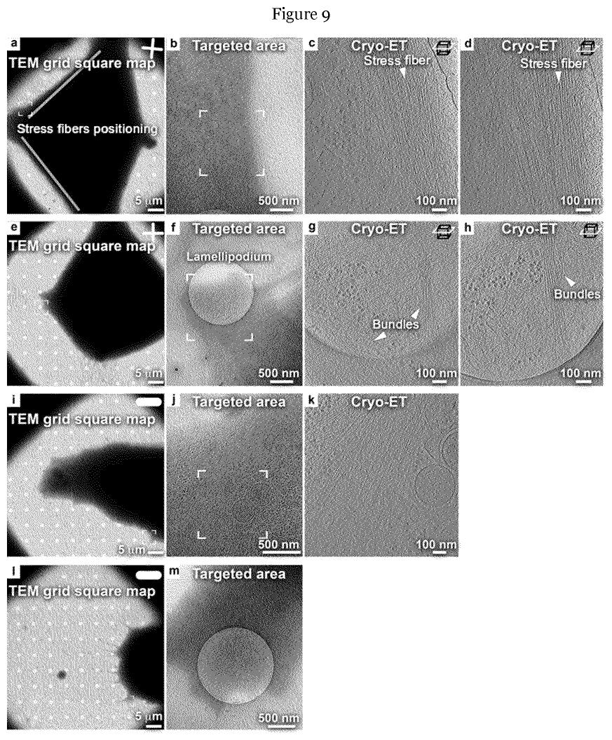

Here, the actin network in Retinal pigment epithelium cells (RPE) as a case of study and as a direct readout of the cellular response to adhesion on the complex patterns will be described. Tailored micropatterns induced reproducible cell morphology on grids (FIG. 2a)^{Ref. 14}. Each pattern elicited a distinguishable actin 3D network^{Refs. 9,15,16}, with spatially distinct peripheral and internal stress fibers, transverse arcs (made of bundled actin filaments) and isotropic branched meshworks. To elucidate the underlying actin organization in these architectures, cellular tomography directly on the thin peripheries of micropatterned-shaped cells was performed (FIG. 2b, FIG. 8a-c). A cell grown on a cross-shaped micropattern (FIG. 2c) was chosen aiming to target peripheral actin stress fibers as indicated by the live-cell actin map (FIG. 2a, upper-left). Cryo-TEM of the selected region exhibited a lamellipodium and a noticeable stress fiber (FIG. 2d, FIG. 9a-d. See FIG. 9e-k for additional examined cells). Cryo-ET of the targeted area revealed the presence of a peripheral bundle of aligned actin filaments comprising a stress fiber and the meshwork of the lamellipodium (FIG. 2e). Cryo-ET on a different, natively thinner, cell periphery displayed a meshwork of individual actin filaments, exhibiting the expected helical structure, and unidentified hexameric macromolecular complexes at the basal and epical cell membranes (FIG. 2f, FIG. 9l-m). To understand the advantages of using an electron microscopy grid comprising a biocompatible layer, such as a SiO2-, graphene-, carbon-, or gold-film, the inventors analysed a functionalized EM support based on an electron microscopy grid comprising Graphene (FIG. 5 and FIG. 6).

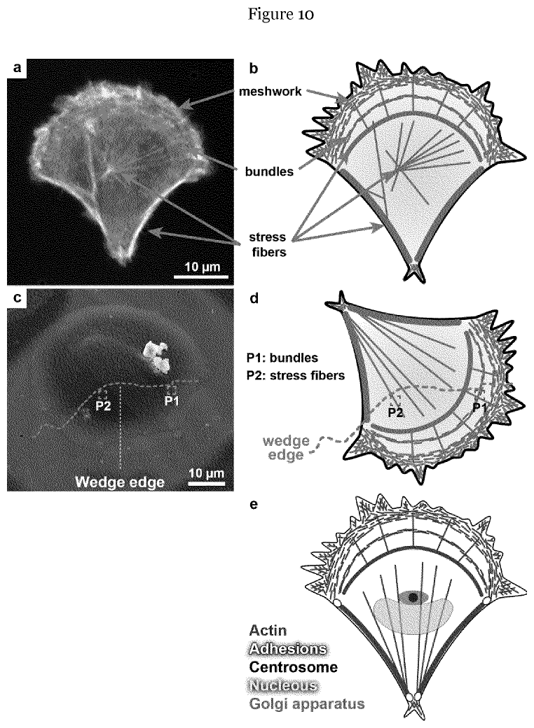

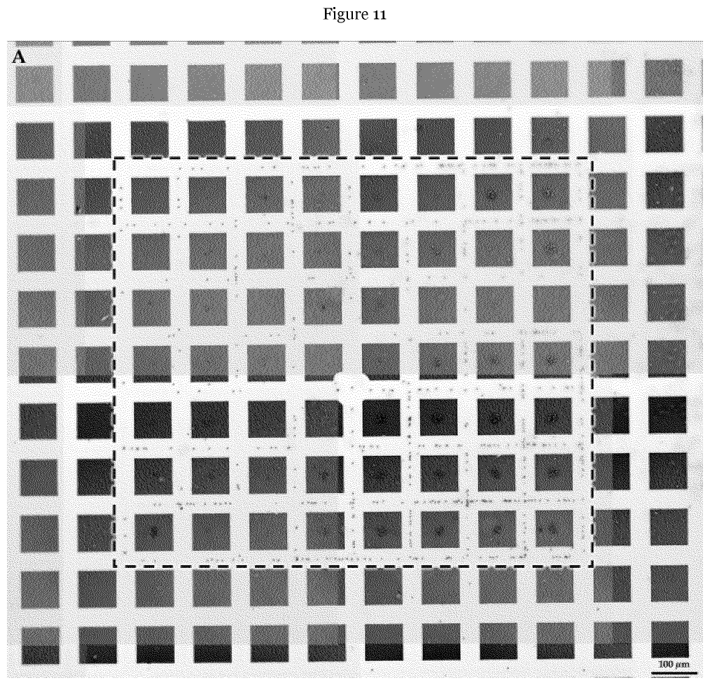

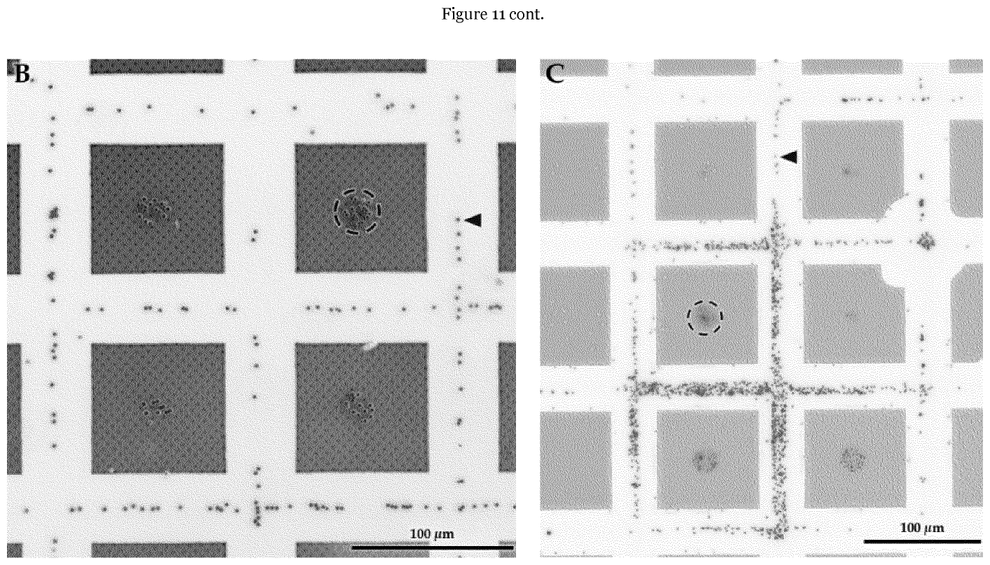

To explore the organization of the cytoskeleton further away from the cell peripheries and to characterize spatially-predictable structures according to live-cell actin maps (FIG. 10a-c), cryo-FIB milling to the micropattern-adherent RPE cells was applied. Cryo-scanning electron microscopy (cryo-SEM) of a patterned grid shows the accurate single cell positioning at the centers of individual grid squares. Multiple different patterns can be generated on the same grid for direct comparison of different cellular architectures. The patterns' identity can be easily identified by direct imaging with low-voltage SEM imaging or the micropattern-adopted cell shape (FIG. 2g, top and bottom panels), facilitating the overlay of the pattern design (FIG. 2g, top). An adherent RPE cell on a crossbow-shape micropattern was selected for thinning by means of cryo-FIB micromachining (FIG. 2h). The majority of the cell material was removed using a single rectangular area (FIG. 2i). This ablates the top of the cell, generating a thin wedge at the basal cell membrane^{Ref. 6}. Cryo-ET at positions 1 and 2, indicated on the wedge (FIG. 2h), displayed a curved transverse arc and a stress fiber, respectively (FIG. 2j-k, FIG. 10d-f). Microtubules were seen lining the stress fibers (FIG. 2k). Interestingly, the ultra-structure revealed that they were not only strictly aligned but embedded in the stress fiber. These structures matched the expected actin and microtubule organization in the crossbow pattern, in which the observed bundles likely form part of the transverse arcs and the microtubules are aligned with the stress fiber at the basal part of the cell (FIG. 2a, upper-right). Such results provide an opportunity to uncover novel insights into cellular biomechanics following controlled cell shaping. Further data processing by semi-automated segmentation of tomographic volumes can deliver quantitative 3D structural information, including angular distributions of individual filaments in different cytoskeletal architectures and inter-filament distances, a level of structural information that is uniquely attainable only by cryo-ET^{Refs. 17,18}. We further envision that the reproducible internal organization, encompassing positioning of cytoskeletal elements and stereotypical organelles organization in response to predetermined external physical cues posed by micropatterns (FIG. 10g), will assist in targeting specific internal structures for structural studies without resorting to challenging correlative approaches under cryogenic conditions.

In conclusion, photo-micropatterning of EM grids contributes to the advancement of refined, routine and user-friendly specimen preparations for in-cell structural biology. It further aids in solving technical challenges that have, thus far, hindered high-throughput FIB thinning preparations. This method will be instrumental for potential automation of the cryo-FIB milling process, deeply impacting the streamlining state-of-the-art cellular cryo-EM pipelines. This approach offers a unique opportunity to generate in-cell integrated insight into the structure and dynamics of macromolecules at nanometer-scale, broadening the scope of questions that can be addressed by state-of-the-art structural biology methods.

Methods

Cell Lines and Culture

Wild type HeLa Kyoto cells, and a double tagged line expressing both green fluorescent protein (GFP)-tagged β-tubulin from a bacterial artificial chromosome (BAC) and mCherry tagged histone from a plasmid construct (H2B-mCherry). HeLa cells were cultured in Dulbecco's modified Eagle's medium (DMEM; ThermoFischer Scientific, Schwerte, Germany), while RPE-1 (Retinal Pigment Epithelial human cells) expressing LifeAct-GFP19 were cultured in DMEM F-12. Cells were incubated at 37° C. with 5% CO2, and supplemented with 10% (v/v) fetal bovine serum (FBS), 2 mM L-glutamine, 100 mg/mL penicillin, 100 mg/mL streptomycin. A 0.5 mg/mL geneticin (G418) for the BAC-tagged lines and Puromycin (1 μg/ml) for cells carrying the plasmids were used. FluoroBrite DMEM (ThermoFischer Scientific, Schwerte, Germany) was used for live cell fluorescence imaging.

Electron Microscopy Grids

Gold (Au) or Titanium (Ti) 200-mesh grids with a holey 12 nm thick SiO2 film, either R2/1, R1/4 or R1/20 (Quantifoil Micro Tools, Jena, Germany) were employed in this study. Titanium-mesh grids, and SiO2 films replacing the commonly used amorphous carbon Quantifoil, provided stiffer and more robust supports for the multiple grid processing and cell culture steps described in the method. Both, titanium (FIG. 2g-h) and SiO2 film were demonstrated to be biocompatible as observed by live-cell imaging (FIG. 1c-d). The commonly used amorphous carbon Quantifoil films were also compatible with the method, yet require sputtering of an additional carbon layer on the support^{Refs. 4,5} for easier handling during cell culture.

Increased amount of film over holes promoted better cell adhesion. R2/1 and R1/4 films were advantageous for direct tomography of peripheral cellular areas, while R1/20 and R1/4 films were more suitable for cellular thinning by cryo-FIB milling as the majority of the film is removed during thinning.

Grid Passivation

One-step: Grids were oxidized and rendered hydrophilic using a low-pressure Diener Femto Plasma cleaner. Grids were place onto a glass slide and both sides were plasma cleaned at 100 W power with a flow rate 10 cm3/min of oxygen gas for 30-40 s. Next, grids were incubated on droplets of poly(l-lysine) grafted with poly(ethylene glycol) (PLL(20)-g[3.5]-PEG(5), SuSoS AG, Dübendorf, Switzerland) at a concentration of 0.5 mg/ml in 10 mM Hepes pH 7.4, for 1 h at room temperature or overnight at 4° C., on a parafilm in a humid chamber (parafilm sealed dish with soaked filter paper). Following passivation, the grids were blotted with filter paper from the side and allowed to dry. No washing of the PLL-Peg was performed.

Two-step: As an alternative, a two-step treatment of the grids was also tested. First, grids were incubated on droplets of 0.01% PLL (Sigma Aldrich, St. Louis, Mo.) on a parafilm in a humid chamber overnight at room temperature. Next, the grids were blotted, but not allowed to dry and incubated for 1-2 h with 50 mg/ml PEG-sva (Laysan Bio, Arab, US).

Both passivation protocols were successful for grid passivation followed by photo-micropatterning, as judged from fluorescence light microscopy imaging of GFP-absorption that was restricted to the PEG-free patterns. However, a one-step PLL-g-PEG passivation was preferred for time optimization purposes. This treatment is especially convenient in the absence of plasma cleaner and can be used following the more commonly employed glow discharge procedures.

Micropatterns were designed in Inkscape (http://www.inkscape.org/) as 8-bit binary files and exported as png files, which can be loaded into the Leonardo software (Alveolé Lab, Paris, France).

Micropatterning and Functionalization of Grids

Nanoablation by a 355 nm Pulse Laser

An inverted confocal Olympus FluoView 1200 (Olympus, Hamburg, Germany) microscope was used, equipped with a UV pulsed laser source of 355 nm (PNV-001525-140, Teem Photonics, Meylan, France), a UPLSAPO 63× (NA 1.35) oil objective, and a standard PMT or GaAsP PMT detectors. The 355 nm laser had an average power of 50 mW, 300 ps pulse width, 1 kHz repetition rate, and a maximum energy per pulse of 20 μJ. Transmission and reflection were observed with a 488 nm laser. The patterns (ROIs) were of circular shape (20, 30 or 40 μm diameter) and made using the Olympus FV 10-ASW software v04.02.03.02. Photo-micropatterning was performed using 10-11% laser power, 40 82 s per pixel and 10 iterations. Individual grid squares were targeted at a time, the film focused and the laser applied. Micropatterning of a 4×4 grid square area (200-mesh grid: ˜260,000 μm2) took ˜8 min. Potentially, a lower magnification objective can be used in order to pattern more grid squares at the same time in order to optimize patterning, provided that the film is flat and at even height to maintain all areas in the focus plane. Titanium grids had a consistent film flatness aiding quick focusing on each grid square, facilitating the micropatterning using this technique.

PRIMO™ (DMD-Based Illumination+Photo-Activator):

An inverted Nikon microscope Ti-E equipped with a CFI Super Plan FLuor 20× ELWD (NA 0.45) lens with high UV-transmission, a Perfect Focus System 3, an ORCA-Flash 4.0 LT CMOS camera (Hamamatsu, Japan), a motorized stage (Märzhäuser, Wetzlar, Germany), and the Primo™ micropatterning module (Alveolé Lab, Paris, France) was used. Grid micropatterning was performed using digital mirror device (DMD) to generate a spatially controlled laser illumination of the sample (Primo™, Alveolé Lab, Paris, France), which provides a resolution limit of ˜1.2 μm. After passivation with PLL-g-PEG, grids were blot-dried from the back with a filter paper and quickly placed with the SiO2 film facing up (away from the objective) on a 1-3 μl of PLPP (4-benzoylbenzyl-trimethylammonium chloride, 14.5 mg/ml) drop in a sealed glass bottom ibidi μ-Dish 35 mm low (ThermoFischer Scientific, Schwerte, Germany). High humidity was kept using water-soaked filter paper inside the dish to avoid PLPP evaporation. The dish, with 1-4 grids at a time, was placed on the microscope stage and photo-patterning was controlled with the μmanager software v1.4.22 by the Leonardo plugin software v4.12 (Alvéole Lab, Paris, France) using the stitching mode and a 375 nm (4.5 mW) laser, applying a dose of 800-1000 mJ/mm² equivalent to ˜30 s per DMD exposition. Micropatterning of an 8×7 grid square area (200-mesh grid: ˜900,000 μm2) took 3-7 min depending on the total dose and grid positioning with respect to the DMD mirror illumination. Grids were promptly retrieved from the PLPP solution, washed in a 300 μl drop of water, and two consecutive washes in 300 μl drops of PBS. Grids were stored wet in PBS at 4° C. in a humid chamber, remaining functional for at least 30 days.

For functionalization following PEG ablation in micropatterns using both methods, grids were incubated at room temperature in a 20 μl drop of either 50 μg/ml fibronectin (ThermoFischer Scientific, Schwerte, Germany), a 50 μg/ml of a GFP-tagged protein, or 50 μg/ml of fibrinogen-488 (ThermoFischer Scientific, Schwerte, Germany) on a parafilm and, subsequently, washed 3 times in 300 μl drops of PBS. Grids incubated with fibronectin remain functional for at least to 10 days in PBS at 4° C. in a humid chamber. The maximum active life time of the micropatterned grids as well as protein functionalization remain unknown. This will also depend on the protein stability itself. All patterning steps and grid treatments were performed under sterile conditions using a Bunsen burner. Grids were handled with a tweezer n° 55 (Dumont, Montignez, Switzerland).

Comparison Between the Two Patterning Approaches:

Due to the pulsing nature of the laser in the first approach, it has to scan the region of interest to be patterned to ablate the anti-fouling agent. The action of the laser leaves an impression on the film that is visible by light microscopy (FIG. 4a-b). The engraving can be further observed in detail by FIB (side view) and SEM (top view) imaging of a grid square (FIG. 4c-d). Importantly, the film engraving at the conditions used did not seem to cause a deterioration of the SiO2 layer. In fact, proper cell adhesion to the (fibronectin-coated) patterns (FIG. 4e-f) or subsequent vitrification of grids appeared unaltered (FIG. 4g). Furthermore, followed by cell settling on the patterns, they strictly adhere and divide on the grid-micropatterned regions, denoting cell viability and the effectiveness of the passivation. Some agglomeration of cells can be appreciated in the FIG. 4e. This can be overcome by optimizing cells seeding conditions using fewer cells/cm2 and less time of seeding (prior transfer to a new cell-free dish) along with use of a cell strainer. Using this method, a directed spatial positioning of cells was attained, which was valuable for cryo-FIB milling (FIG. 4g-j), demonstrating and further supporting the advantages of micropatterning for the cryo-ET pipeline optimization.

While the Primo device takes 30 s per DMD run (for a dose of 1000 mJ/mm² and covering a 3×2 grid squares on a 200-mesh grid), the 355 nm-pulse laser patterning takes ˜10-15 s per grid square considering a disk-shaped pattern of 20-30 μm diameter. A user familiar with the 355 nm laser technique can pattern a 4×4 grid square area in ˜8 min, while the Primo technology covers a similar area in ˜1 min. While the Primo device is faster to create micropatterned areas, the 355 nm-pulse scanning laser can yield a much higher spatial lateral resolution limited by the light diffraction (PSF) and equivalent to ˜250 nm, in comparison to the Primo performance that is limited to ˜1.5 μm.

At least 50 grids have been seeded with either HeLa or RPE cells obtaining reproducible results with cells settling and adhering to the micropatterned areas.

Cell Seeding

Non-patterned grids were plasma cleaned or glow discharged. Cells were detached from cell culture flasks using 0.05% trypsin-EDTA and seeded on pre-treated Quantifoil grids in glass bottom ibidi μ-Dish 35mm high (ThermoFischer Scientific, Schwerte, Germany).

Cells were seeded on fibronectin micropatterned surfaces right after being passed through a cell 40 μm pore-size cell strainer (Corning, Amsterdam, Netherlands) at a density of 2×10⁴ cells/cm² for HeLa and 8×10³ cells/cm² for RPE cell lines. After seeding, grids were incubated for 1.5-2 h for HeLa cells or 20-35 min RPE cells. Next, cells were transferred to a new cell-free dish and incubated at 37° C. with 5% CO2 to allow adhesion to the grids. Transfer to a new dish was beneficial to remove cells that were non-specifically attached to areas outside the patterns. Cells were vitrified 4-6 h post-transfer for RPE cells (to attain a higher number of individual grid squares with a single cell) or after overnight incubation for HeLa cells.

Live Cell Confocal Imaging

Time lapse imaging of HeLa cells on grids (FIG. 1c, d) was performed in a Zeiss LSM 880 Airyscan microscope (Carl Zeiss, Jena, Germany) using confocal detectors and a Plan-Apochromat 20× (NA 0.8) objective. Field of view: 425×425 μm2. Pixel size of 149 nm, and 1 μm as z-step (total z-depth: 32 μm). Pixel dwell time: 0.28 μs. Master gain 850 for both channels. GFP was detected using a 488 nm line of Argon laser with a 1.5% power and a 490-550 nm bandpass emission filter. RFP was detected using a 561 nm DPSS laser at a 0.15% power, and a bandpass emission filter of 570-660 nm. Time-lapse imaging was performed with 1 h time resolution using the Zen Black 2.3 SP1 software v14.0.15.201 and MyPic VBA macro^{Ref. 17}. XZ images of the dish surface reflection was acquired and processed by the MyPic VBA macro to define axial position for z-stack acquisition at each time point. Each stack was post-processed in Fiji^{Ref. 18}. Briefly, channels were split, maximum intensity projections made, channels were combined into a single image per time point, and all time points combined into a movie stack.

Zeiss Airyscan microscopy

AiryScan microscopy of RPE cells on patterned grids (FIG. 2a) was performed on a Zeiss LSM 880 AiryScan microscope (Carl Zeiss, Jena, Germany), using an AiryScan detector and a C-Apochromat 40× (NA 1.2) water immersion objective. Optimal sampling conditions for AiryScan acquisitions were achieved by selecting SR (super-resolution) scanning modality. Pixel size of 50 nm and a 225 nm z-step (total z-depth: 10-15 μm). Pixel dwell time: 0.64-1.18 μs. Master gain: 850-900. LifeAct-GFP was detected using a 488 nm line of Argon laser with a power of 1.5-2% and a 495-550 nm bandpass emission filter. Stack datasets were post-processed in Zen Black 2.3 SP1 software v14.0.15.201 (Zeiss) to combine the multiple Airyscan 32-detector array images into deconvolved final images with high SNR and resolution.

Widefield Microscopy Imaging

Epifluorescence images (FIG. 4, 5) were recorded using a Zeiss Axio Observer.Z1 widefield microscope (Carl Zeiss, Jena, Germany) with a AxioCam MRm CCD camera, a A-Plan lox (NA 0.25) Ph1 and a LD-Plan Neofluar 20× (NA 0.4) Ph2 Corr objectives. GFP was imaged with a 38 HE filter set and mCherry with a 43 HE filter set. Cells were imaged at 37° and 5% CO2 with the Zen (blue edition) 2.3 software v2.3.69.1000. Images were processed histogram adjusted, and cropped in Fiji.

Vitrification

Grids were blotted from the reverse and immediately plunged into a liquid ethane or ethane/propane mixture at liquid nitrogen temperature using a Leica EM GP plunger (Leica Microsystems, Vienna, Austria). The plunger was set to 37° C., 99% humidity, and blot time of 2 s for R2/1, and 2.5 s for R1/4 and R1/20 grids. The frozen grids were stored in sealed boxes in liquid nitrogen until further processing.

Cryo-Scanning Electron Microscopy and Focused Ion Beam Milling

Cryo-FIB lamella preparations were performed as described in Ref. 5, on a dedicated dual-beam microscope with a cryo-transfer system and a cryo-stage (Aquilos, ThermoFisher Scientific, Brno, Czech Republic). Plunge frozen grids were fixed into autogrids modified for FIB preparation (Max Planck Institute of Biochemistry, Martinsried, Germany), mounted into a shuttle (ThermoFisher Scientific) and transferred into the dual-beam microscope through a load-lock system. During FIB operation, samples were kept at constant liquid nitrogen temperature using an open nitrogen-circuit, 360° rotatable cryo-stage. To improve sample conductivity and reduce curtaining artifacts during FIB milling, the samples were first sputter-coated with platinum (10 mA, 20 s) and then coated with organometallic platinum using the in situ gas injection system (GIS, ThermoFisher Scientific, Netherlands) operated at room temperature, 10.6 mm stage working distance and 7 s gas injection time. Appropriate positions for FIB preparations were identified and recorded in the MAPS 3.3 software (ThermoFisher Scientific, Brno, Czech republic), and eucentric height refined per position. Lamellae or wedges were prepared using Gallium ion beam at 30 kV at stage tilt angles of 20° for lamellae and 12°-13° for wedges. Lamella or wedge preparations were conducted in a stepwise rough milling, starting with high currents of 1 nA, 5 □m away from the area of interest, gradually reduced to lower currents, down to 50 pA for the final cleaning steps. Progress of the milling process was monitored using the scanning electron beam operated at 10 kV and 50 pA (or 2 kV for visualization of micropatterns). For improved conductivity of the final lamella for specimens intended for phase plate tomography, we again sputter coated the grid after cryo-FIB preparation with platinum (10 mA, 3 s). Grids were stored in sealed boxes in liquid nitrogen until further processing.

Cryo-Electron Tomography

Cryo-electron microscopy data were collected on a Titan Krios microscope operated at 300 kV (ThermoFisher Scientific, Netherlands) equipped with a field-emission gun, a Quantum post-column energy filter (Gatan, Pleasanton, Calif., USA), a K2 Summit direct detector camera (Gatan) and a Volta phase plate (ThermoFisher Scientific, Netherlands). Data were recorded in dose-fractionation mode using acquisition procedures in SerialEM software v3.7.2^{Ref. 21}. Prior to the acquisition of tilt-series, montages of the entire lamella were acquired at ˜2 nm/pix. Tilt-series using a dose symmetric scheme were collected in nano-probe mode, EFTEM magnification 42,000× corresponding to pixel size at the specimen level of 3.37 Å, 3-4 μm defocus, tilt increment 2° with constant dose for all tilts, total dose ˜120 e−/Å2. The pre-tilt of lamellae with respect to the grid plane due to cryo-FIB milling at shallow angles (10-15°) was corrected for by tilting the stage on the microscope. Conventional tilt-series, Volta phase plate (VPP), were acquired at the same settings with an objective aperture and a beam tilt of 4 mrad for autofocusing (tomograms in FIG. 2e, f; FIG. 9). A fraction of the tomographic tilt-series were acquired with the VPP (tomograms in FIG. 1g; FIG. 2j, k). Alignment and operation of the Volta phase plate were essentially carried out as described previously, applying a beam tilt of 10 mrad for autofocusing^{Ref. 4}. For defocus data, a total of 30 tomograms were acquired on the peripheral areas of 13 micropatterned cells (from all micropattern designs from FIG. 2b). A total of 31 VPP tomograms were acquired from 8 wedges, equivalent to 8 cells grown on crossbow-, cross-, dumbbell-, oval-, and disk-shape micropatterns.

Data Processing

Prior to tilt-series alignment, the projection movies were corrected for beam induced drift in the SerialEM plugin. Tilt series alignment and tomographic reconstructions were performed using the IMOD software package, version 4.9.0^{Ref. 21}. In absence of fiducial gold nanoparticles in the FIB-lamellae, alignment of tilt-series images was performed with patch-tracking. Final alignment of the tilt-series images was performed using the linear interpolation option in IMOD without CTF correction. Aligned images were binned to the final pixel size of 13.48 Å. For tomographic reconstruction, the radial filter options were left at their default values (cut off, 0.35; fall off, 0.05). Tomograms from FIG. 2e and FIG. 10c-d were treated with an anisotropic nonlinear diffusion denoising algorithm to improve signal-to-noise ratio.

Photo-Micropatterning by a 355 Nanoablation UV-Laser

The inventors used a second method of photo-micropatterning by ablating the PLL-g-PEG passivation layer in a spatially-control manner using a 355 nm-pulse laser setup (see methods). Due to the pulsing nature of the laser, it has to scan the region of interest to be patterned to ablate the anti-fouling agent. The action of the laser leaves an impression on the film that is visible by light microscopy (FIG. 4a-b). The engraving can be further observed in detail by FIB (side view) and SEM (top view) imaging of a grid square (FIG. 4c-d). The observed spiky structures are likely accumulated water at the pulsing spots, which enhance the roughness of the film surface. Importantly, the film engraving did not seem to cause a detrimental effect on the SiO2 layer. In fact, proper cell adhesion to the (fibronectin-coated) patterns (FIG. 4e-f) or subsequent vitrification of grids appeared unaltered (FIG. 4g). Furthermore, followed by cell settling on the patterns, they adhere and divide on the grid micropatterned regions (always restricted in it), denoting cell viability and the effectiveness of the passivation. Some agglomeration of cells can be appreciated in the FIG. 4e, this can be overcome by optimizing cells seeding conditions using fewer cells/cm2 and less time of seeding (prior transfer to a new dish cell-free) along with use of a cell strainer. Using this method, a directed spatial positioning of cells was attained, which was valuable for cryo-FIB milling (FIG. 4g-j), demonstrating and further supporting the advantages of micropatterning for the cryo-pipeline optimization. We have also tested unconventional materials that render stiffer and user-friendly grids for better handling. We used titanium-mesh grids and replaced the commonly used amorphous carbon for firmer SiO2 films. Both, titanium (FIG. 2g-h) and SiO2 film demonstrated to be biocompatible as observed by live-cell imaging (FIG. 1c-d). Here, we have used two different methods for photo-micropatterning of EM grids. While the Primo device takes 30 s per DMD run (for a dose of 1000 mJ/mm2 and covering a 3×2 grid squares regions in a grid of mesh 200), the 355 nm-pulse laser patterning takes ˜10-15 s per grid square considering a disk-shaped pattern of 20-30 μm size. A user familiar with the 355 nm laser technique can pattern a 4×4 grid square area in ˜8 min, while Primo does a similar area in ˜1 min. While the Primo device is faster to create micropatterned areas, the 355 nm-pulse scanning laser can yield a much higher spatial lateral resolution given by the light diffraction (PSF) and equivalent to ˜250 nm, while the Primo performance is limited to ˜1.5 μm.

### Example 2: Design of a Human Neural Network on a Chip

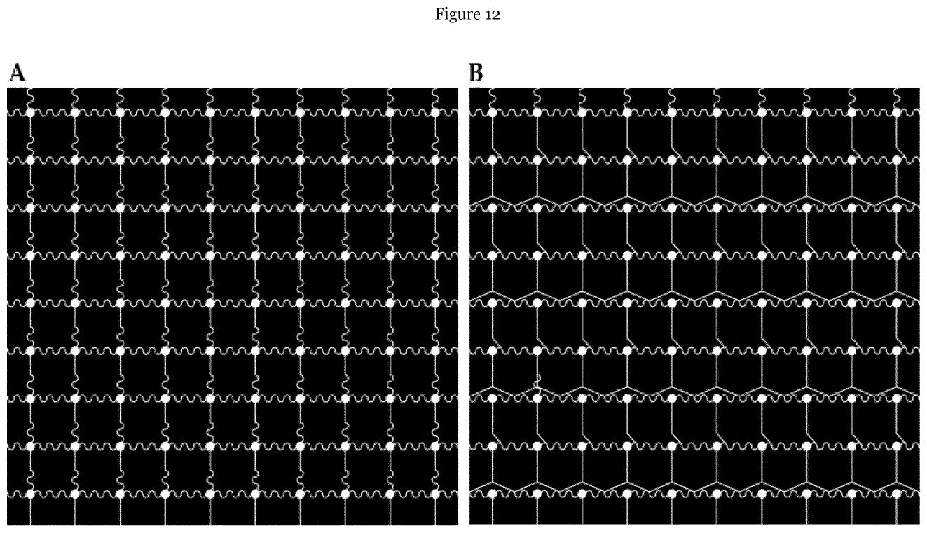

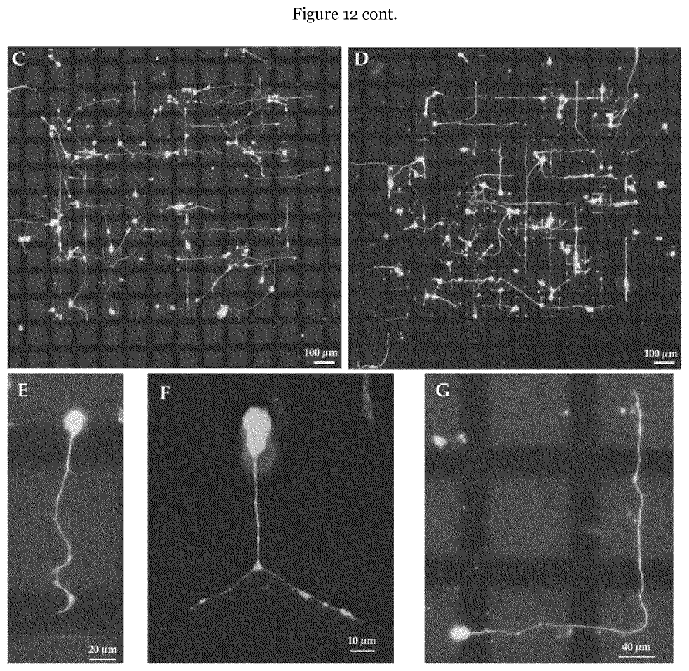

The inventors developed a method for producing a circuit of cells, comprising the functionalized electron microscopy support according to this invention, and at least two cells. The circuit of cells can, for example, grow on a device, such as a chip. Said cells can be neurons, hepatocytes, myocytes, cardiomyocytes, stem cells, stem cell progenitor cells, trophoblasts, astrocytes, glial cells, enterocytes, hepatic cells, kidney cells, endothelial cells, epithelial cells, such as biliary epithelial cells, syncytiotrophoblasts, cytotrophoblasts, mesenchymal cells, inner cochlea cells, outer cochlea cells, and/or trophoblasts. As a proof of principle, the inventors developed a human neural network growing on a functionalized electron microscopy support according to this invention (FIG. 12).

The micropattern was coated with laminin protein for human neuron adherence, and grids were seeded with induced human stem cells and differentiated to neurons (day-6 post seeding) on a grid. Human neurons can be observed by fluorescence microscopy due to a soluble protein (Ngn2-GFP) spread across the cells. Neurons are observed following the micropatterned circuit (FIG. 12e-g). Light microscopy image of a neuron (day-6 post seeding) growing on a micropattern with strong curvature corresponding to the curly lines of the circuit (FIG. 12e), a neuron challenged by the bypass area of a circuit (FIG. 12f), and a neuron changing direction at the center (disk micropatterned area) of a grid square (FIG. 12g), and extending for about 5 grid squares displaying the growth ability of the neurons and the circuit capacity to guide them.

### REFERENCES

The references are:
1. Kalbrandt, W. Science 343, 1443-1444 (2014). doi:10.1126/science.1251652
2. Pfeffer, S. & Mahamid, J. Curr Opin Struct Biol 52, 111-118 (2018). doi:10.1016/j.sbi.2018.08.009
3. Beck, M. & Baumeister, W. Trends Cell Biol 26, 825-837 (2016). doi:10.1016/j.tcb.2016.08.006
4. Mahamid, J. et al. Science 351, 969-972 (2016). doi:10.1126/science.aad8857
5. Schaffer, M. et al. J Struct Biol 197, 73-82 (2017). doi:10.1016/j.jsb.2016.07.010
6. Rigort, A. et al. Proc Natl Acad Sci USA 109, 4449-4454 (2012). doi:10.1073/pnas.1201333109
7. Dubochet, J. & Sartori Blanc, N. Micron 32, 91-99 (2001)
8. Azioune, A., Carpi, N., Tseng, Q., Thery, M. & Piel, M. Methods Cell Biol 97, 133-146 (2010). doi:10.1016/50091-679X(10)97008-8
9. Thery, M. J Cell Sci 123, 4201-4213 (2010). doi:10.1242/jcs.075150
10. Strale, P. O. et al. Adv Mater 28, 2024-2029 (2016). doi:10.1002/adma.201504154
11. Thery, M., Jimenez-Dalmaroni, A., Racine, V., Bornens, M. & Julicher, F. Nature 447, 493-496 (2007). doi:10.1038/nature05786
12. Thery, M. et al. Nat Cell Biol 7, 947-953 (2005). doi:10.1038/ncb1307
13. Arnold, J. et al. Biophys J 110, 860-869 (2016). doi:10.1016/j.bpj.2015.10.053
14. Engel, L. et al. Preprint at https://doi.org/10.1101/657072 (2019).
15. Thery, M. et al. Proc Natl Acad Sci USA 103, 19771-19776 (2006). doi:10.1073/pnas.0609267103
16. Senger, F. et al. Preprint at http://dx.doi.org/10.1101/578799 (2019).
17. Jasnin, M. et al. Proc Natl Acad Sci USA 110, 20521-20526 (2013). doi:10.1073/pnas.1320155110
18. Jasnin, M. & Crevenna, A. H. Biophys J 110, 817-826 (2016). doi:10.1016/j.bpj.2015.07.053
19. Vignaud, T. et al. J Cell Sci 125, 2134-2140 (2012). doi:10.1242/jcs.104901
20. Rigort, A. et al. J Struct Biol 172, 169-179 (2010). doi:DOI 10.1016/j.jsb.2010.02.011
21. Kremer, J. R., Mastronarde, D. N. & McIntosh, J. R. J Struct Biol 116, 71-76 (1996). doi:http://dx.doi.org/10.1006/jsbi.1996.0013
22. Fukuda, Y., Laugks, U., Lucic, V., Baumeister, W. & Danev, R. J Struct Biol 190, 143-154 (2015). doi:DOI 10.1016/j.jsb.2015.03.004
23. Politi, A. Z. et al. Nat Protoc 13, 1445-1464 (2018). doi:10.1038/nprot.2018.040
24. Schindelin, J. et al. Nat Methods 9, 676-682 (2012). doi:10.1038/nmeth.2019

1. A functionalized electron microscopy support comprising at least one or several area(s) functionalized with a substrate allowing for the adhesion of a biological specimen, particularly a living cell,
wherein the functionalized area(s) is/are at least partially or is completely surrounded by at least passivation layer substance, wherein said substance at least partially repels live cells and/or does not allow for, or at least partially reduces the adhesion of live cells.

2. The functionalized electron microscopy support according to claim 1, wherein the electron microscopy support is an electron microscopy grid, particularly comprising or consisting of gold, copper, molybdenum, titanium or platinum.

3. The functionalized electron microscopy support according to claim 1 or 2, wherein said electron microscopy support optionally comprises a biocompatible film, preferably a SiO2-, graphene, carbon-, gold-film, or silicon nitride (Si₃N₄), particularly a SiO2-film.

4. The functionalized electron microscopy support according to any one of claims 1 to 3, wherein the passivation layer substance comprises a repelling agent, particularly wherein the repelling agent comprises a polyether, polyethylene glycol, and/or poly(L-lysine)-grafted-poly(ethylene glycol) (PLL-g-PEG).

5. The functionalized electron microscopy support according to any one of claims 1 to 4, wherein the substrate for the adhesion of live cells comprises proteins, glycoproteins, and/or polysaccharides, particularly wherein the substrate for the adhesion of live cells comprises at least one extracellular matrix component selected from the group comprising laminin, fibronectin, vitronectin, integrin, collagen, fibrillin, elastine, and glycosaminoglycane, Arginylglycylaspartic acid (RGD) peptides, and Arginylglycylaspartic acid (RGD)-conjugated chemicals or proteins.

6. The functionalized electron microscopy support according to any one of claims 1 to 5, further comprising at least one living cell or fixed cell in at least one area.

7. A method of preparing the functionalized electron microscopy support as defined in any one of claims 1 to 6, said method comprising:
a) Providing an electron microscopy support,
b) Coating said electron microscopy support with a passivation layer substance, particularly wherein said substance at least partially repels live cells and/or does not allow for, or at least partially reduces the adhesion of live cells,
c) Photo-micropatterning said coated electron microscopy support obtained in b).

8. The method according to claim 7, wherein the photo-micropatterning step is a contactless and/or mask-free photo-micropatterning step, particularly wherein the photo-micropatterning step locally removes the passivation layer substance of step b) to provide areas which are essentially free of passivation layer substances.

9. The method according to any one of claims 7 or 8, wherein the photo-micropatterning step is performed with a pulse laser, particularly with a 300 nm to 370 nm pulse laser, more particularly with a 355 nm pulse laser, or said step is performed by UV-illumination with a digital micro-mirror device (DMD).

10. The method according to any one of claims 7 to 9, further comprising a step d) comprising functionalizing with substrate allowing for the adhesion of live cells in those areas where the photo-micropatterning step removed the passivation layer substance applied in step b).

11. The method according to any one of claims 7 to 10, wherein the passivation layer substance comprises a repelling agent, particularly wherein the repelling agent comprises a polyether, particularly polyethylene glycol or poly(L-lysine)-grafted-poly(ethylene glycol) (PLL-g-PEG).

12. The method according to any one of claims 7 to 11, said method further comprising step e), wherein at least one living cell is seeded in at least one area functionalized with a substrate allowing for the adhesion of live cells.

13. The method according to any one of claims 7 to 12, wherein the substrate for the adhesion of live cells comprises proteins, glycoproteins, polysaccharides.

14. The method according to any one of claims 7 to 13, said method further comprising step e), wherein the living cell is fixed or vitrified to the support.

15. Use of functionalized electron microscopy support as defined in any one of claims 1 to 6, or of an functionalized electron microscopy support prepared in a method according to any one of claims 7 to 14 in the analysis of biomolecules or of adherent cells, particularly comprising at least one method selected from the group comprising microscopy, confocal microscopy, vitrification, cryo-FIB milling, transmission electron microscopy, cryo-light microscopy, cryo-electron tomography, cryo-focused ion beam (FIB) analysis, cryo-correlative light-electron microscopy (Cryo-CLEM), and/or cellular micromachining by cryo-FIB milling.

16. A method for producing a circuit of cells, comprising the steps of:
a) Providing a functionalized electron microscopy support according to any one of claims 1 to 6, or a functionalized electron microscopy support prepared in a method according to any one of claims 7 to 14,
b) Providing at least two cells, and
c) Seeding said cells in at least one area of said electron microscopy support functionalized with a substrate allowing for the adhesion of said cells,
thereby generating the circuit of cells on the electron microscopy support.

17. The method according to claim 16, wherein the cells are selected from neurons, hepatocytes, myocytes, cardiomyocytes, stem cells, stem cell progenitor cells, trophoblasts, astrocytes, glial cells, enterocytes, hepatic cells, kidney cells, endothelial cells, epithelial cells, such as biliary epithelial cells, syncytiotrophoblasts, cytotrophoblasts, mesenchymal cells, inner cochlea cells, outer cochlea cells, trophoblasts, preferably wherein the cells are human cells, such as human neurons.

18. The method according to claim 16 or 17, wherein said cells belong to the same cell type or to at least two different cell types.

19. A circuit of cells produced by a method according to any one of claims 16 to 18.

20. A circuit of cells according to claim 19 for use in medicine.

21. A circuit of cells according to claim 19 for use in the treatment and/or prevention of a brain disease, spinal-cord injury, a heart disease, liver failure, kidney failure, deafness, a degenerative disease, such as a neurodegenerative disease, and/or a skin disease, or in the manufacture of a medicament against a brain disease, spinal-cord injury, a heart disease, liver failure, kidney failure, deafness, a degenerative disease, such as a neurodegenerative disease, and/or a skin disease.

22. Use of a circuit of cells according to claim 19 to repair at least one damaged circuit in or on the human body, for example to repair a damaged neuronal circuit.

23. A method of treatment and/or prevention of a brain disease, spinal-cord injury, a heart disease, liver failure, kidney failure, deafness, a degenerative disease, such as a neurodegenerative disease, and/or a skin disease in a subject, the method comprising the step of administering to the subject a circuit of cells according to claim 19.

24. The method according to claim 23, wherein said subject is a mammal, such as a human, a mouse, rat, guinea pig, rabbit, cat, dog, monkey, preferably a human, for example a human patient, more preferably a human patient suffering from a brain disease, spinal-cord injury, a heart disease, liver failure, kidney failure, deafness, a degenerative disease, such as a neurodegenerative disease, and/or a skin disease.
